(19) United States
(12) Patent Application Publication
(10) Pub. No.: US 2026/0354031 A1
(43) Pub. Date: Nov. 5, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Fu-Ting SUNG, Yangmei City (TW); Che-Wei KUO, Hsinchu City (TW)

(21) Appl. No.: 19/197,700

(22) Filed: May 2, 2025

(51) Int. Cl. H10N 50/01; G11C 11/16; H10N 50/10; H10N 50/80

(52) U.S. Cl. CPC H10N 50/01; H10N 50/10; H10N 50/80; G11C 11/161

(57) ABSTRACT

Memory devices may include side spacer arrangements and may be manufactured using techniques which facilitate and permit removal of side spacer portions from memory device top electrode surfaces when interconnect structure recesses are formed over memory device top electrodes. For example, materials and/or thicknesses of side spacer portions formed on top electrode surfaces may be controlled to prevent etching resistance of the side spacer portions and permit exposure of the top electrode surfaces by interconnect structure recesses. As a result, interconnect structures (e.g., vias) formed in the interconnect structure recesses may contact the top electrode surfaces without intervening residual spacer material between the interconnect structures and the top electrode surfaces, thereby reducing resistance and creating reliable electrical connections between top electrodes and interconnect structures to increase memory device performance and/or reliability.

### BACKGROUND

A semiconductor device may include a non-volatile memory, which is able to store data in the absence of power. Non-volatile memory technologies include magneto-resistive random-access memory (MRAM), phase change random access memory (PC-RAM), and resistive random access memory (RRAM), among other examples. These non-volatile memory technologies are compatible with complementary metal-oxide-semiconductor (CMOS) logic fabrication processes, which enables logic and memory circuitry to be integrated onto the same semiconductor device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1D are diagrams of an example semiconductor device including example semiconductor memory structures described herein.

FIGS. 2A-2E are diagrams of an example implementation of forming a semiconductor device described herein.

FIG. 3 is a diagram of an example implementation of a portion of a semiconductor device described herein.

FIGS. 4A-4N are diagrams of an example implementation of forming a portion of a semiconductor device described herein.

FIG. 5 is a diagram of an example implementation of a portion of a semiconductor device described herein.

FIGS. 6A-6L are diagrams of an example implementation of forming a portion of a semiconductor device described herein.

FIG. 7 is a flowchart of an example process associated with forming a semiconductor device including a semiconductor memory structure.

FIG. 8 is a flowchart of an example process associated with forming a semiconductor device including a semiconductor memory structure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An MRAM cell may include a memory device having a magnetic tunnel junction (MTJ) structure arranged vertically between a bottom electrode and a top electrode. A memory device may be connected to a metallization structure through a via electrically connected to the top electrode. However, during memory device fabrication, side spacers of a memory device may be deposited on the top electrode. In some cases, certain metal oxides that are used as a material for the side spacers may be resistant to etching, and difficult to remove from the top electrode. As a result, unremoved portions of the side spacers that remain on a top electrode may hinder and/or prevent reliable electrical connections between a top electrode and a via, which may reduce memory device performance and/or reliability.

In some implementations, memory devices may include side spacer arrangements and may be manufactured using techniques which facilitate and permit removal of side spacer portions from memory device top electrode surfaces when interconnect structure recesses are formed over memory device top electrodes. For example, materials and/or thicknesses of side spacer portions formed on top electrode surfaces may be controlled to prevent etching resistance of the side spacer portions and permit exposure of the top electrode surfaces by interconnect structure recesses. As a result, interconnect structures (e.g., vias) formed in the interconnect structure recesses may contact the top electrode surfaces without intervening residual spacer material between the interconnect structures and the top electrode surfaces, thereby reducing resistance and creating reliable electrical connections between top electrodes and interconnect structures to increase memory device performance and/or reliability.

Additionally, in the example implementations described herein, interconnect and metallization structures in memory and logic regions may be manufactured using the same etching and deposition processes. Accordingly, processing to manufacture the interconnect and metallization structures in a memory region and corresponding interconnect and metallization structures in a logic region requires fewer masks and fewer steps than processing to manufacture other arrangements of metallization and interconnect structures. The simplified device manufacturing may result in fewer design errors, further increasing device performance and reliability.

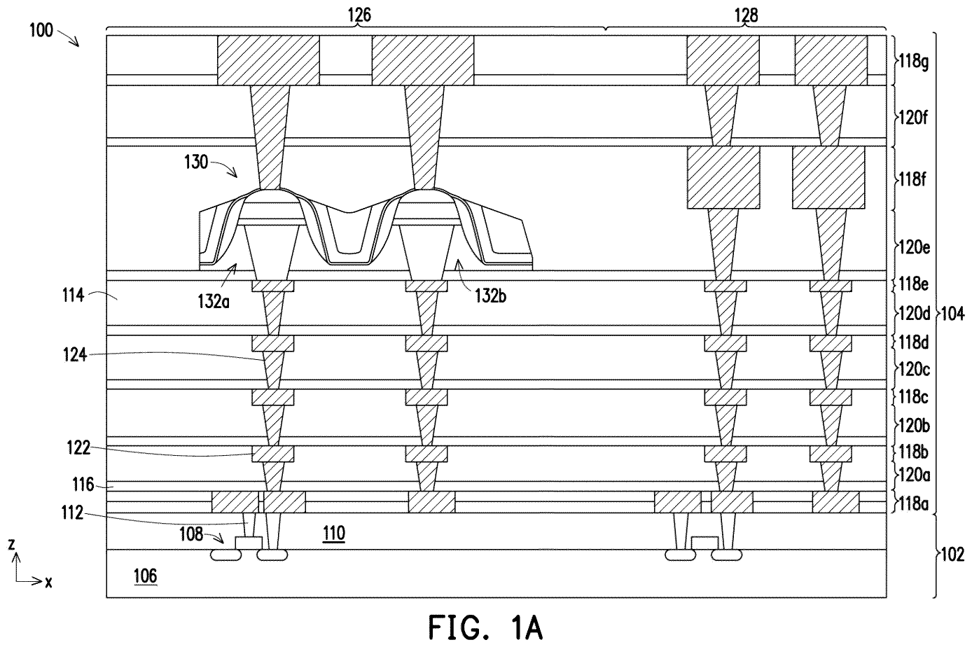

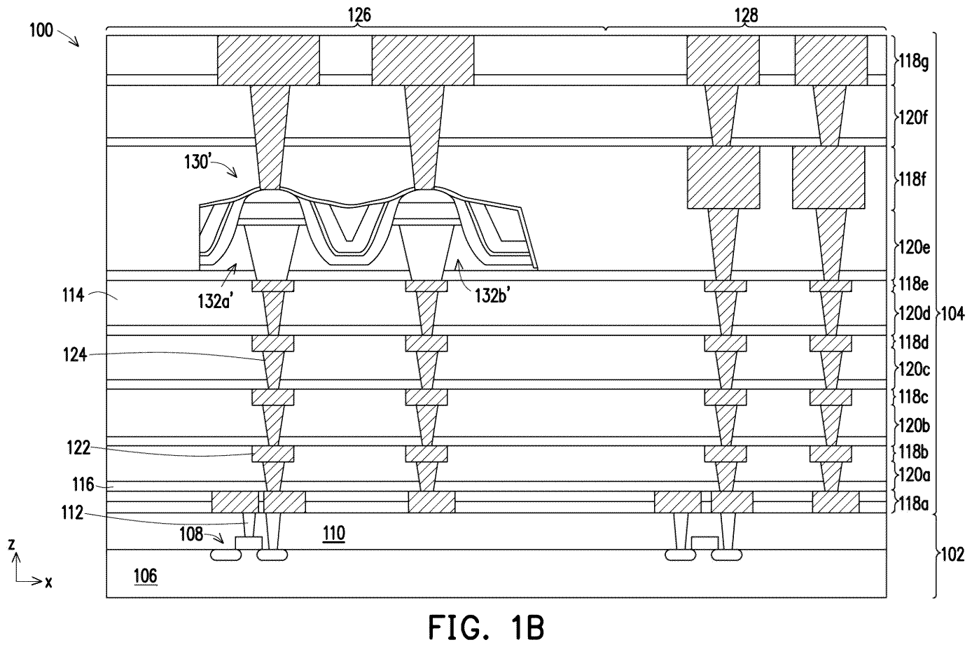

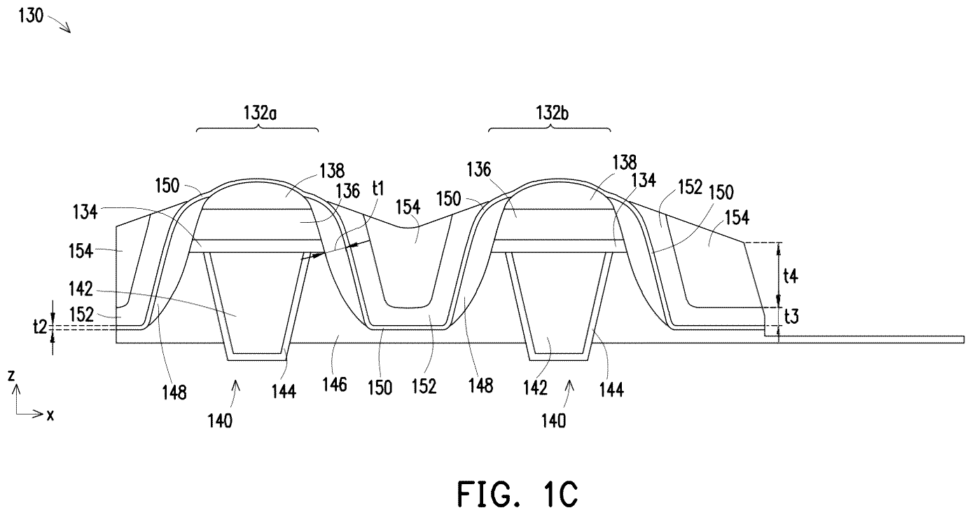

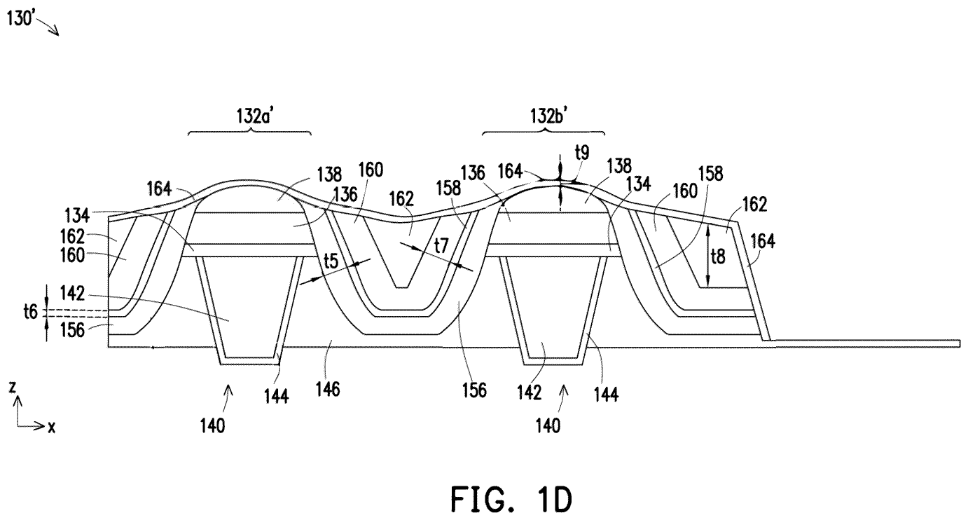

FIGS. 1A-1D are diagrams of an example semiconductor device 100 described herein. The semiconductor device 100 may include a system on chip (SoC) device, a logic device such as a central processing unit (CPU) or a graphics processing unit (GPU), a memory device (e.g., a high bandwidth memory (HBM) device), an image sensor device (e.g., a complementary metal-oxide-semiconductor (CMOS) image sensor device), and/or another type of semiconductor device.

FIGS. 1A and 1B illustrate cross-section views of the semiconductor device 100. As shown in FIGS. 1A and 1B, the semiconductor device 100 may include a device layer 102 and an interconnect layer 104 arranged in a z-direction in the semiconductor device 100 with respect to the device layer 102. For example, the interconnect layer 104 may be located above the device layer 102. As another example, the interconnect layer 104 may be located below the device layer 102.

The interconnect layer 104 may include conductive structures that are arranged to carry signals and/or provide power distribution throughout the semiconductor device 100. In some implementations, the semiconductor device 100 includes interconnect layers 104 above and below the device layer 102. A first interconnect layer 104 on a first side of the device layer 102 may be used for signal propagation throughout the semiconductor device 100, and a second interconnect layer 104 on an opposing second side of the device layer 102 may be used for power distribution in the semiconductor device 100.

The device layer 102 includes a substrate 106 of the semiconductor device 100. The substrate 106 may correspond to a portion of a semiconductor wafer on which the semiconductor device 100 is formed. The substrate 106 may include a silicon (Si) substrate, a substrate formed of a material including silicon, a III-V compound semiconductor material substrate such as gallium arsenide (GaAs), a silicon on insulator (SOI) substrate, or another type of substrate. The substrate 106 may extend in an x-direction and/or in a y-direction in the semiconductor device 100 such that the top and bottom surfaces of the substrate 106 are approximately orthogonal to the z-direction in the semiconductor device 100.

Integrated circuit devices 108 may be included in and/or on the substrate 106 in the device layer 102 of the semiconductor device 100. The integrated circuit devices 108 may include front end transistor structures (e.g., front end planar transistor structures, front end fin field effect transistor (finFET) structures, front end gate all around (GAA) transistor structures), pixel sensors, capacitors, resistors, inductors, photodetectors, transceivers, transmitters, receives, optical circuits, and/or other types of front end semiconductor devices.

A front end transistor structure may include a plurality of source/drain regions, which may correspond to doped regions of the substrate 106, separated by a channel region in the substrate 106. In some implementations, the source/drain regions are doped with a first type of dopant (e.g., a p-type dopant such as boron (B) and/or gallium (Ga), an n-type dopant such as phosphorous (P) and/or arsenic (As)), and the channel region is doped with a second type of dopant that is different from the first type of dopant. The front end transistor structure may include a gate structure over and/or around the channel region. A gate dielectric layer of the front end transistor structure may be included between the gate structure and the channel region. The gate structure may include a polysilicon gate, a metal gate with a high dielectric constant (high-k) gate dielectric layer such as hafnium oxide (HfOₓ such as HfO₂), and/or another type of gate structure.

A dielectric layer 110 is included over the substrate 106. The dielectric layer 110 includes an interlayer dielectric (ILD) layer, an etch stop layer (ESL), and/or another type of dielectric layer. The dielectric layer 110 includes dielectric material(s) that enable various portions of the substrate 106 and/or the integrated circuit devices 108 to be selectively etched or protected from etching, and/or to electrically isolate the integrated circuit devices 108 in the device layer 102. The dielectric layer 110 includes a silicon nitride (SiₓN_{y}), an oxide (e.g., a silicon oxide (SiOₓ) and/or another oxide material), and/or another type of dielectric material. The dielectric layer 110 may extend in the x-direction and/or in the y-direction in the semiconductor device 100. Contacts 112 (e.g., source/drain contacts, gate contacts) may extend through the dielectric layer 110 and between the integrated circuit devices 108 and the interconnect layer 104. The contacts may electrically connect the integrated circuit devices 108 to the interconnect layer 104. The contacts 112 may include vias, plugs, and/or another type of elongated electrically conductive structures. The contacts 112 may include tungsten (W), cobalt (Co), ruthenium (Ru), titanium (Ti), aluminum (Al), and/or gold (Au), among other electrically conductive materials.

The interconnect layer 104 includes a plurality of dielectric layers (e.g., back end dielectric layers) that are arranged in a direction (e.g., the z-direction) that is approximately perpendicular to the top surface of the substrate 106. The dielectric layers may include ILD layers 114 and ESLs 116 that are arranged in an alternating manner in the z-direction. The ILD layers 114 and the ESLs 116 may extend in the x-direction and/or in the y-direction in the semiconductor device 100.

The ILD layers 114 may each include a low dielectric constant (low-k) oxide material such as silicon oxide (SiOₓ) or undoped silicate glass (USG). Additionally and/or alternatively, the ILD layers 114 may each include a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 114 includes an extreme low dielectric constant (ELK) dielectric material having a dielectric constant that is less than approximately 2.5. Examples of ELK dielectric materials include carbon doped silicon oxide (C-SiOₓ), amorphous fluorinated carbon (α-CₓF_{y}), parylene, bis-benzocyclobutenes (BCB), polytetrafluoroethylene (PTFE), a silicon oxycarbide (SiOC) polymer, porous HSQ, porous methyl silsesquioxane (MSQ), porous polyarylether (PAE), and/or porous silicon oxide (SiOₓ), among other examples.

The ESLs 116 may each include a silicon nitride (SiₓN_{y}), silicon carbide (SiC), silicon oxynitride (SiON), and/or another suitable dielectric material. In some implementations, an ILD layer 114 and an ESL 116 include different dielectric materials to provide etch selectivity to enable various structures to be formed in the interconnect layer 104. For example, the ILD layers 114 may each include a low-k dielectric material such as USG, and the ESLs 116 may each include a high-k dielectric material such as silicon nitride (SiₓN_{y}) or silicon carbide (SiC), such that a dielectric constant of one or more ESLs 116 is greater than a dielectric constant of one or more ILD layers 114. Additionally and/or alternatively, two or more ESLs 116 may include different materials. For example, one or more first ESLs 116 may include silicon nitride (SiₓN_{y}), and one or more second ESLs 116 may include silicon carbide (SiC).

The interconnect layer 104 includes a plurality of conductive structures that are arranged in a plurality of layers. The conductive structures may be electrically coupled and/or physically coupled with one or more of the integrated circuit devices 108 in the device layer 102. The conductive structures provide electrical routing that enables signals and/or power to be provided to and/or from the integrated circuit devices 108.

The layers of conductive structures may include a plurality of layers 118a-118g that are vertically arranged and alternate with a plurality of layers 120a-120f in the z-direction (e.g., vertically alternate). The layers 118a-118g each include a layer of metallization structures 122 (e.g., metal lines), and the layers 120a-120f each include a layer of interconnect structures 124 (e.g., vias).

The layers 118a-118g of metallization structures 122 may be referred to as M-layers. For example, a layer 118a of metallization structures 122 (referred to as a metal-0 (M0) layer) may be located at the bottom of the interconnect layer 104 and may be coupled with the device layer 102. In particular, the metallization structures 122 in the M0 layer may be coupled with the contacts 112 (e.g., a contact layer referred to as “CO” layer) of the integrated circuit devices 108 in the device layer 102. A layer 118b of metallization structures 122 (referred to as a metal-1 layer (M1) layer) may be located above the layer 118a of metallization structures 122 in the interconnect layer 104, a layer 118c of metallization structures 122 (referred to as a metal-2 layer (M2) layer) may be located above the layer 118b of metallization structures 122, and so on.

A layer 120a of interconnect structures 124 (referred to as a via-1 (V0) layer) may be included between the M0 layer and the M1 layer to interconnect the M0 layer and the M1 layer, a layer 120b of interconnect structures 124 (referred to as a via-2 (V1) layer) may be included between the M1 layer and the M2 layer to interconnect the M1 layer and the M2 layer, and so on.

The metallization structures 122 may include a combination of trenches, metallization layers, conductive traces, and/or other types of conductive structures. The interconnect structures 124 may include a combination of vias, interconnects, and/or other types of conductive structures. The metallization structures 122 and the interconnect structures 124 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included between the dielectric layers of the interconnect layer 104 and the metallization structures 122, and/or between the dielectric layers of the interconnect layer 104 the interconnect structures 124. The one or more liner layers may include barrier liners, adhesion liners, and/or another type of liners. Examples of materials for the one or more liners include tantalum nitride (TaN) and/or titanium nitride (TiN), among other examples.

In some implementations, the topmost layer of conductive structures (e.g., a topmost layer of metallization structures 122, a topmost layer of interconnect structures 124) may be coupled to connection structures at the top of the semiconductor device 100. The connection structures may include solder balls, solder bumps, contact pads (e.g., land grid array (LGA) pads), contact pins (e.g., pin grid array (PGA) pins), under bump metallization (UBM) connections, microbumps, ball grid array (BGA) balls, controlled collapse chip connection (C4) bumps, and/or other types of connection structures. In some implementations, the topmost layer of conductive structures (e.g., a topmost layer of metallization structures 122, a topmost layer of interconnect structures 124) may be coupled to bonding structures, such as bonding pads and/or bonding vias.

As further shown in FIGS. 1A and 1B, the semiconductor device may be divided into a memory region 126 and a logic region 128. The memory region 126 may include memory devices and corresponding circuitry. The memory devices may include MRAM devices, PC-RAM devices, and/or RRAM devices, among other examples of devices used for memory storage. The logic region 128 may include logic devices and corresponding circuitry to process data and perform computations. The logic devices may include transistors arranged to perform designated algorithms.

FIG. 1A shows a semiconductor structure 130 including a plurality of memory devices 132a and 132b included in the interconnect layer 104 of the semiconductor device 100, and FIG. 1B shows a semiconductor structure 130′ including a plurality of memory devices 132a′ and 132b′ included in the interconnect layer 104 of the semiconductor device 100. The semiconductor structure 130 and the semiconductor structure 130′ may extend through and/or is included in one or more dielectric layers in the interconnect layer 104, such as one or more ILD layers 114 and/or one or more ESLs 116. In some implementations, an integrated circuit device 108 is electrically coupled to one or more of the memory devices 132a and/or 132b, or to the memory devices 132a′ and/or 132b′ to form a memory cell (e.g., an MRAM cell or another type of resistance-based memory cell) in the semiconductor device 100. In some implementations, a memory device 132a 132a′, 132b, and/or 132b′ is a non-volatile memory device configured to store data in the absence of power. In some implementations, a memory device 132a 132a′, 132b, and/or 132b′ is configured to perform another function in the semiconductor device 100.

FIG. 1C is a diagram of the semiconductor structure 130. As shown in FIG. 1C, each memory device 132a and 132b includes a stacked structure with a bottom electrode layer 134, an MTJ structure 136 on the bottom electrode layer 134, and a top electrode layer 138 on the MTJ structure 136. The MTJ structure 136 may include a fixed layer and a free layer (e.g., ferromagnetic layers), separated by a tunnel barrier layer, that selectively allow quantum tunneling of electrons. The free and fixed layers may include ferrous materials including a combination of iron (Fe) and one or more of cobalt (Co), boron (B), and/or nickel (Ni), among other examples, and the tunnel barrier layer may include a crystalline material, such as magnesium oxide (MgO) and/or another suitable material. In operation, a magnetic direction associated with the free layer may be aligned in parallel with a magnetic direction associated with the fixed layer to place the MTJ structure 136 into an ON or 1 state, in which quantum tunneling is allowed, and the MTJ structure 136 exhibits a lower resistance. On other hand, the magnetic direction associated with the free layer may be reversed (that is, anti-parallel) relative to the magnetic direction associated with the fixed layer, to place the MTJ structure 136 into an OFF or 0 state, in which quantum tunneling is disallowed, and the MTJ structure 136 exhibits a higher resistance.

The bottom electrode layer 134 is a bottom electrode of each memory device 132a and 132b, and the top electrode layer 138 is a top electrode of each memory device 132a and 132b. The bottom electrode layer 134 and the top electrode layer 138 may include one or more electrically conductive materials. Examples include metals such as molybdenum (Mo), nickel (Ni), iridium (Ir), and chromium (Cr), as well as metal nitrides such as titanium nitride (TiN) or tantalum nitride (TaN), among other examples.

The memory devices 132a and 132b may be electrically coupled and/or physically coupled to a bottom interconnect structure 140 (e.g., via). The bottom interconnect structures 140 may each include one or more conductive structures in the interconnect layer 104, where the conductive structures include a fill layer 142 and a liner layer 144. The fill layers 142 may include tungsten (W), cobalt (Co), ruthenium (Ru), titanium (Ti), aluminum (Al), copper (Cu), gold (Au), and/or a combination thereof, among other examples of electrically conductive materials. The liner layers 144, which are included on side and bottom surfaces of the bottom interconnect structures 140, are disposed between the dielectric layers of the interconnect layer 104 and the fill layers 142, and/or between a metallization structure 122 under a bottom interconnect structure 140 and the fill layer 142. The liner layers 144 may include barrier liners, adhesion liners, and/or another type of liners. Examples of materials for the liner layers 144 include tantalum nitride (TaN) and/or titanium nitride (TiN), among other examples. The bottom interconnect structures 140 may each be formed in and/or through one or more of the ILD layers 114 and/or ESLs 116.

In some implementations, each of the bottom interconnect structures 140 is disposed under a bottom electrode layer 134 in the z-direction, and is in direct physical contact with a bottom surface of the bottom electrode layer 134. A dielectric layer 146 (e.g., USG) may be disposed around the bottom interconnect structures 140, and under portions of the bottom electrode layer 134.

First spacer layers 148 are disposed on and along side surfaces of the bottom electrode layer 134, the MTJ structure 136, and a portion of the top electrode layer 138 for each of the memory devices 132a and 132b. As shown in FIG. 1C, the first spacer layers 148 may extend onto surfaces of the dielectric layer 146 below a bottom edge of the bottom electrode layer 134. The first spacer layers 148 may be in direct physical contact with side surfaces of the bottom electrode layer 134, the MTJ structure 136, and the portion of the top electrode layer 138. The first spacer layers 148 may include a dielectric material such as a nitride (e.g., a silicon nitride (SiₓN_{y}) and/or another nitride material), and/or another suitable material. The first spacer layers 148 may protect the MTJ structure 136 from moisture.

A second spacer layer 150 (also referred to herein as a “capping spacer layer”) is disposed on side surfaces of the first spacer layers 148, on horizontal (e.g., x-direction) surfaces of the dielectric layer 146, and on top surfaces of parts of the top electrode layers 138. As shown in FIG. 1C, portions of the second spacer layer 150 may extend below a bottom edge of the bottom electrode layer 134 and/or below bottom edges of the first spacer layers 148. The second spacer layer 150 may be in direct physical contact with the side surfaces of the first spacer layers 148, surfaces of the dielectric layer 146, and the top surfaces of the parts of the top electrode layers 138. The second spacer layer 150 may include a dielectric material such as an oxide (e.g., a silicon oxide (SiOₓ) and/or another oxide material), and/or another suitable material. In some implementations, the second spacer layer 150 includes a material having a low etch selectivity with respect to an ILD layer 114 that may be formed over the memory devices 132a and 132b, so that when the ILD layer 114 is etched to form interconnect structure recesses over the top electrode layers 138, the second spacer layer 150 may also be etched to expose top surfaces of the top electrode layers 138. For example, a ratio of the etch rates of the ILD layer 114, and of the second spacer layer 150 may be approximately 1:1 so that the ILD layer 114 and the second spacer layer 150 can be etched using the same etchant to form recesses exposing top surfaces of the top electrode layers 138. In some implementations, the second spacer layer 150 and an ILD layer 114 that may be formed over the memory devices 132a and 132b may include materials that have the same or similar etch rates for a particular etchant that may be used to form the interconnect structure recesses over the top electrode layers 138. In some implementations, the second spacer layer 150 and an ILD layer 114 that may be formed over the memory devices 132a and 132b may include the same or similar materials. The second spacer layer 150 may protect the top electrode layers 138 from chemical damage.

Third spacer layers 152 are disposed on side surfaces and horizontal (e.g., x-direction) surfaces of the second spacer layer 150. As shown in FIG. 1C, the third spacer layers 152 may extend below a bottom edge of the bottom electrode layer 134. The third spacer layers 152 may be in direct physical contact with the side and horizontal surfaces of the second spacer layer 150. The third spacer layers 152 are not disposed on (e.g., leave exposed) portions of the second spacer layer 150 that are on the top electrode layers 138. Portions of the second spacer layer 150 are interposed between the first spacer layers 148 and the third spacer layers 152. The third spacer layers 152 may include a dielectric material such as a silicon oxycarbide (SiOC) polymer, and/or another suitable material. The third spacer layers 152 may protect the MTJ structure 136 and other layers under the third spacer layers 152 from chemical damage. The second spacer layer 150 may function as an adhesion layer between the first spacer layers 148 and the third spacer layers 152.

Fourth spacer layers 154 are disposed on side surfaces and horizontal (e.g., x-direction) surfaces of the third spacer layers 152. As shown in FIG. 1C, the fourth spacer layers 154 may extend below a bottom edge of the bottom electrode layer 134. The fourth spacer layers 154 may be in direct physical contact with the side and horizontal surfaces of the third spacer layers 152. The fourth spacer layers 154 are not disposed on (e.g., leave exposed) portions of the second spacer layer 150 that are on the top electrode layers 138. The third spacer layers 152 are interposed between the second spacer layer 150 and the fourth spacer layers 154. The fourth spacer layers 154 may include a dielectric material such as tetraethyl orthosilicate (TEOS), and/or another suitable material. The fourth spacer layers 154 may protect the MTJ structure 136 and other layers under the fourth spacer layers 154 from chemical damage.

As shown in FIG. 1C, a thickness t2 of the second spacer layer 150 may be smaller than thicknesses t1, t3, and t4 of the first spacer layers 148, the third spacer layers 152, and the fourth spacer layers 154, respectively. As explained in more detail herein, because the second spacer layer 150 is etched to expose top surfaces of the top electrode layers 138, the smaller thickness t2 of the second spacer layer 150 facilitates complete etching of the second spacer layer 150 when forming interconnect structure recesses over the top electrode layers 138. The smaller thickness t2 in comparison to the thicknesses t1, t3, and t4 of the remaining spacer layers ensures that the entire portion of the second spacer layer 150 to be etched to expose the top surfaces of the top electrode layers 138 can be removed in an etch operation.

FIG. 1D is a diagram of the semiconductor structure 130′. As shown in FIG. 1D, the components 134-146 in the semiconductor structure 130′ are the same as the components 134-146 in the semiconductor structure 130. However, the arrangement of spacer layers 156, 158, 160, 162, and 164 in the semiconductor structure 130′ differs from that of spacer layers 148, 150, 152, and 154 in the semiconductor structure 130. In more detail, first spacer layers 156 are disposed on and along side surfaces of the bottom electrode layer 134, the MTJ structure 136, and a portion of the top electrode layer 138 for each of the memory devices 132a′ and 132b′. As shown in FIG. 1D, the first spacer layers 156 may extend onto surfaces of the dielectric layer 146 below a bottom edge of the bottom electrode layer 134. The first spacer layers 156 may be in direct physical contact with side surfaces of the bottom electrode layer 134, the MTJ structure 136, and the portion of the top electrode layer 138. The first spacer layers 156 may include a dielectric material such as a nitride (e.g., a silicon nitride (SiₓN_{y}) and/or another nitride material), and/or another suitable material. The first spacer layers 156 may protect the MTJ structure 136 from moisture.

Second spacer layers 158 (are disposed on side surfaces of the first spacer layers 156, and on horizontal (e.g., x-direction) surfaces of the first spacer layers 156, which are on horizontal surfaces of the dielectric layer 146. As shown in FIG. 1D, portions of the second spacer layer 158 may extend below a bottom edge of the bottom electrode layer 134. The second spacer layers 158 may be in direct physical contact with the side and horizontal surfaces of the first spacer layers 156. The second spacer layers 158 may include a dielectric material such as an oxide (e.g., a silicon oxide (SiOₓ) and/or another oxide material), and/or another suitable material. The second spacer layers 158 may protect the top electrode layers 138, MTJ structures 136, and/or bottom electrode layers 134 from chemical damage.

Third spacer layers 160 are disposed on side surfaces and horizontal (e.g., x-direction) surfaces of the second spacer layers 158. As shown in FIG. 1D, the third spacer layers 160 may extend below a bottom edge of the bottom electrode layer 134. The third spacer layers 160 may be in direct physical contact with the side and horizontal surfaces of the second spacer layer 158. The second spacer layers 158 are interposed between the first spacer layers 156 and the third spacer layers 160. The third spacer layers 160 may include a dielectric material such as a silicon oxycarbide (SiOC) polymer, and/or another suitable material. The third spacer layers 160 may protect the MTJ structure 136 and other layers under the third spacer layers 160 from chemical damage. The second spacer layers 158 may function as adhesion layers between the first spacer layers 156 and the third spacer layers 160.

Fourth spacer layers 162 are disposed on side surfaces and horizontal (e.g., x-direction) surfaces of the third spacer layers 160. As shown in FIG. 1D, the fourth spacer layers 162 may extend below a bottom edge of the bottom electrode layer 134. The fourth spacer layers 162 may be in direct physical contact with the side and horizontal surfaces of the third spacer layers 160. The third spacer layers 160 are interposed between the second spacer layers 158 and the fourth spacer layers 162. The fourth spacer layers 162 may include a dielectric material such as tetraethyl orthosilicate (TEOS), and/or another suitable material. The fourth spacer layers 162 may protect the MTJ structure 136 and other layers under the fourth spacer layers 162 from chemical damage.

A fifth spacer layer 164 (also referred to herein as a “capping spacer layer”) is disposed on top surfaces of the first through fourth spacer layers 156-162, and on top surfaces of the top electrode layers 138. The fifth spacer layer 164 extends onto side surfaces of the first through fourth spacer layers 156-162, and onto a bottom portion of the dielectric layer 146. The fifth spacer layer 164 may include a dielectric material such as an oxide (e.g., a silicon oxide (SiOₓ) and/or another oxide material), and/or another suitable material. In some implementations, the fifth spacer layer 164 includes a material having a low etch selectivity with respect to an ILD layer 114 that may be formed over the memory devices 132a′ and 132b′, so that when the ILD layer 114 is etched to form interconnect structure recesses over the top electrode layers 138, the fifth spacer layer 164 may also be etched to expose top surfaces of the top electrode layers 138. For example, a ratio of the etch rates of the ILD layer 114, and of the fifth spacer layer 164 may be approximately 1:1 so that the ILD layer 114 and the fifth spacer layer 164 can be etched using the same etchant to form recesses exposing top surfaces of the top electrode layers 138. In some implementations, the fifth spacer layer 164 and an ILD layer 114 that may be formed over the memory devices 132a′ and 132b′ may include materials that have the same or similar etch rates for a particular etchant that may be used to form the interconnect structure recesses over the top electrode layers 138. In some implementations, the fifth spacer layer 164 and an ILD layer 114 that may be formed over the memory devices 132a′ and 132b′ may include the same or similar materials. The fifth spacer layer 164 may protect the top electrode layers 138 from chemical damage.

As shown in FIG. 1D, a thickness t9 of the fifth spacer layer 164 may be smaller than thicknesses t5, t7, and t8 of the first spacer layers 156, the third spacer layers 160, and the fourth spacer layers 162, respectively. As explained in more detail herein, because the fifth spacer layer 164 is etched to expose top surfaces of the top electrode layers 138, the smaller thickness t9 of the fifth spacer layer 164 facilitates complete etching of the fifth spacer layer 164 when forming interconnect structure recesses over the top electrode layers 138. The smaller thickness t9 in comparison to the thicknesses t5, t7, and t8 of the spacer layers 156, 160, and 162 ensures that the entire portion of the fifth spacer layer 164 to be etched to expose the top surfaces of the top electrode layers 138 can be removed in an etch operation. In some implementations, a thickness t6 of the second spacer layer 158 is approximately equal to the thickness t9 of the fifth spacer layer 164.

The semiconductor structure 130 includes two memory devices 132a and 132b, and the semiconductor structure 130′ includes two memory devices 132a′ and 132b′. Alternatively, the semiconductor structure 130 and/or the semiconductor structure 130′ may include more or fewer than two memory devices.

As indicated above, FIGS. 1A-1D are provided as examples. Other examples may differ from what is described with regard to FIGS. 1A-1D.

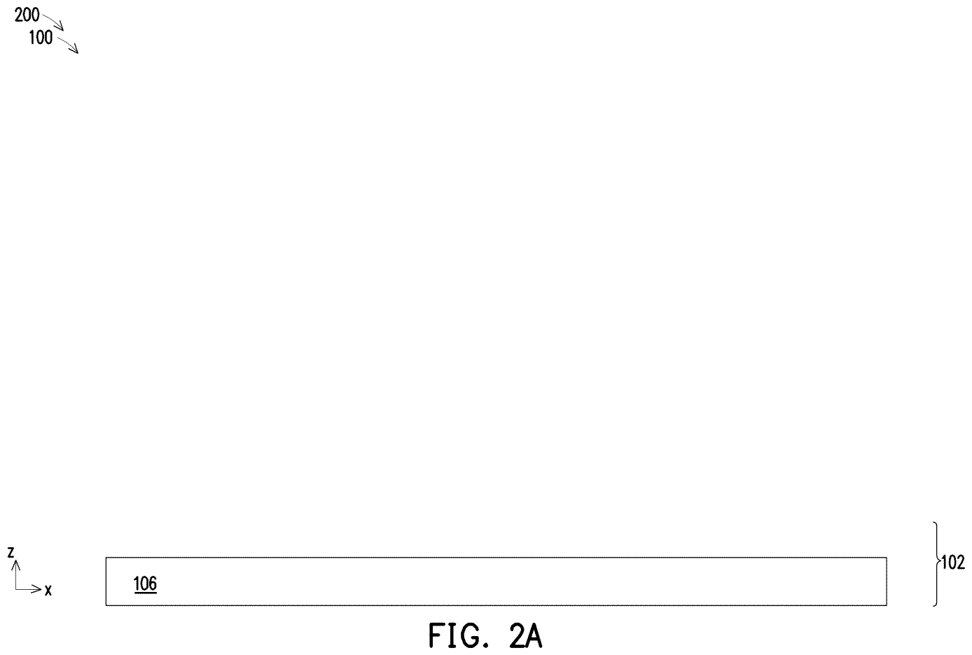

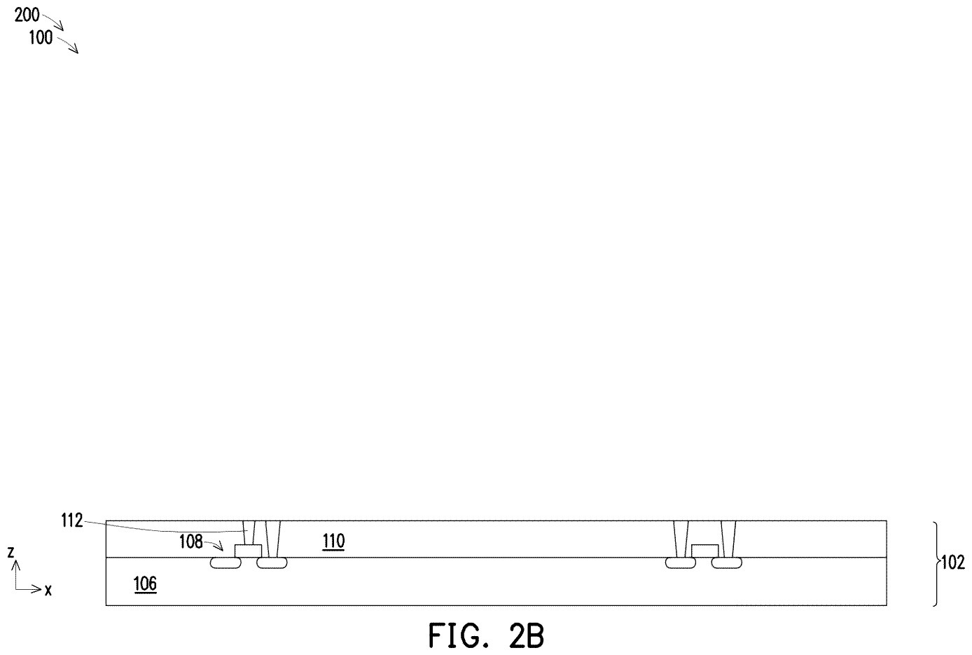

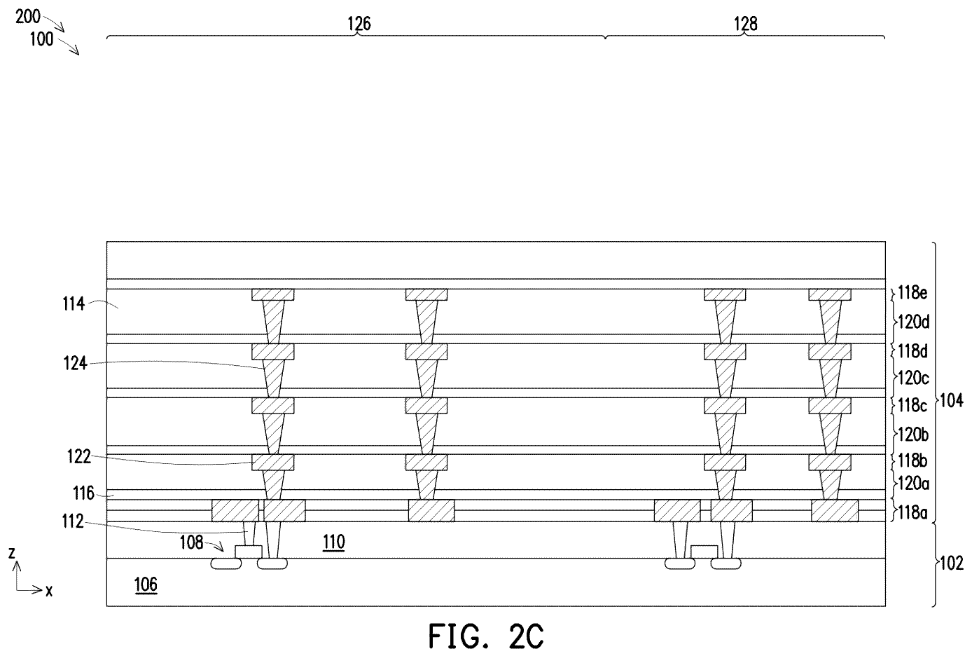

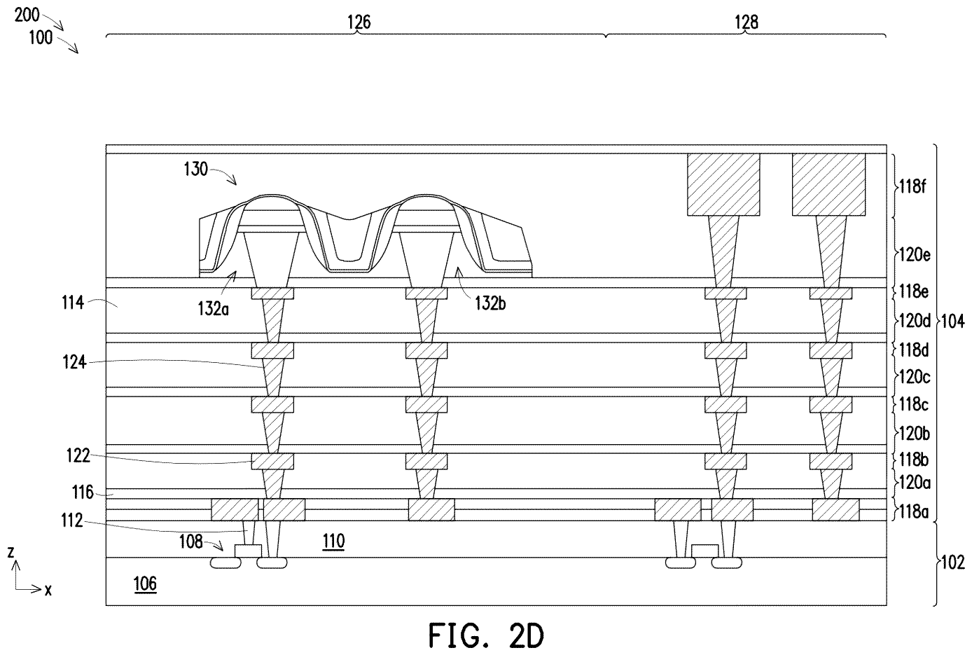

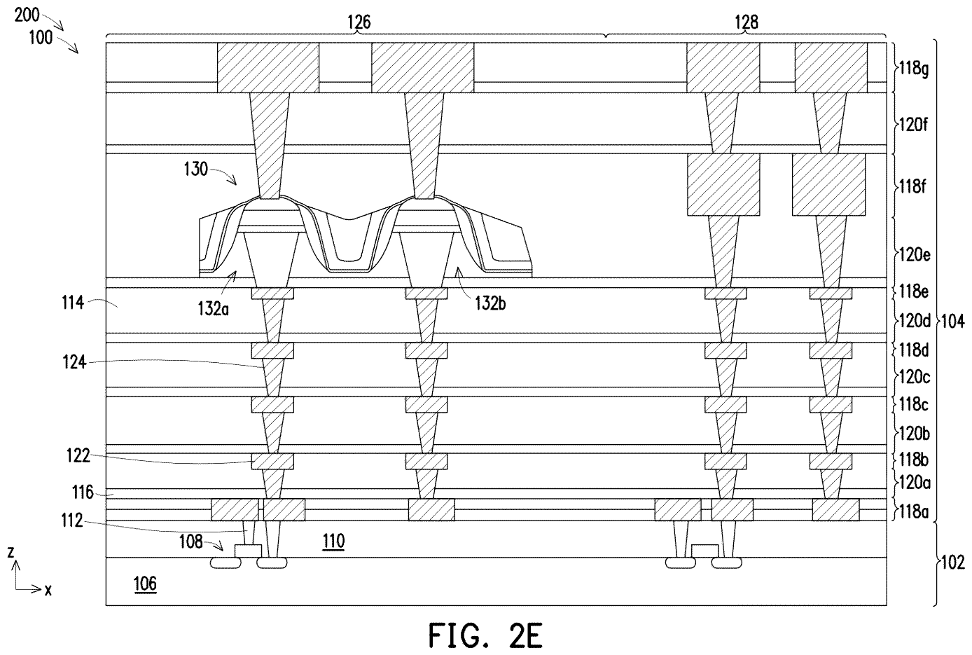

FIGS. 2A-2E are diagrams of an example implementation 200 of forming the semiconductor device 100 described herein. In some implementations, one or more of the semiconductor processing operations described in connection with FIGS. 2A-2E may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

Turning to FIG. 2A, the substrate 106 is provided. The substrate 106 may be provided in the form of a semiconductor wafer such as a silicon (Si) wafer, an SOI wafer, and/or another type of semiconductor work piece. The semiconductor device 100 may be formed on the semiconductor wafer with other semiconductor devices.

As shown in FIG. 2B, the integrated circuit devices 108 may be formed in and/or on the substrate 106 in the device layer 102 of the semiconductor device 100. One or more semiconductor processing tools may be used to form one or more portions of the integrated circuit devices 108. For example, an ion implantation tool may be used to dope one or more regions in the substrate 106 with one or more types of dopants to form well regions, implant regions, and/or other types of doped regions in the substrate 106 for the integrated circuit devices 108. As another example, a deposition tool may be used to perform various deposition operations to deposit layers and/or structures of the integrated circuit devices 108, and/or to deposit photoresist layers for etching the substrate 106 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate 106 and/or portions of the deposited layers to form the integrated circuit devices 108. As another example, a planarization tool may be used to planarize portions of the integrated circuit devices 108. As another example, a plating tool may be used to deposit metal structures and/or layers of the integrated circuit devices 108.

As further shown in FIG. 2B, a deposition tool is used to deposit the dielectric layer 110 over and/or on the substrate 106 and over and/or on the integrated circuit devices 108. A deposition tool may be used to deposit the dielectric layer 110 using a physical vapor deposition (PVD) technique, an atomic layer deposition (ALD) technique, a chemical vapor deposition (CVD) technique, an oxidation technique, and/or another suitable deposition technique. In some implementations, a planarization tool may be used to perform a planarization operation such as a chemical mechanical planarization (CMP) operation to planarize the dielectric layer 110 after the dielectric layer 110 is deposited.

As further shown in FIG. 2B, the contacts 112 of the integrated circuit devices 108 may be formed through the dielectric layer 110. The contacts 112 may be formed in recesses in the dielectric layer 110. In some implementations, a pattern in a photoresist layer is used to etch the dielectric layer 110 to form the recesses. In these implementations, a deposition tool may be used to form the photoresist layer on the dielectric layer 110. An exposure tool may be used to expose the photoresist layer to a radiation source to pattern the photoresist layer. A developer tool may be used to develop and remove portions of the photoresist layer to expose the pattern. An etch tool may be used to etch the dielectric layer based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 110 based on a pattern to form the recesses.

The contacts 112 may be formed in the recesses. In some implementations, a contact 112 (e.g., a gate contact) is formed on a gate structure of an integrated circuit device 108. In some implementations, a contact 112 (e.g., a source/drain contact) is formed on a source/drain region of an integrated circuit device 108. A deposition tool may be used to deposit the material of the contacts 112 in the recesses using a CVD technique, a PVD technique, an ALD technique, an electroplating technique, and/or another suitable deposition technique. The material of the contacts 112 may be deposited in one or more deposition operations. In some implementations, a seed layer is first deposited, and the material of the contacts 112 is deposited on the seed layer. In some implementations, a planarization tool is used to perform a planarization operation (e.g., a CMP operation) to planarize the contacts 112 after the contacts 112 are deposited such that the tops of the contacts 112 are approximately co-planar with the top of the dielectric layer 110.

As shown in FIG. 2C, a first portion of the interconnect layer 104 of the semiconductor device 100 is formed above the dielectric layer 110. One or more deposition tools are used to deposit alternating layers of ILD layers 114 and ESLs 116 in the first portion of the interconnect layer 104 of the semiconductor device 100. In this way, the ILD layers 114 and ESLs 116 may be arranged in the z-direction in the semiconductor device 100. One or more deposition tools may be used to deposit each of the ILD layers 114 and each of the ESLs 116 using a PVD technique, an ALD technique, a CVD technique, an oxidation technique, and/or another suitable deposition technique. In some implementations, a planarization tool may be used to planarize the ILD layers 114 and/or the ESLs 116 after the ILD layers 114 and/or the ESLs 116 are deposited.

As further shown in FIG. 2C, a deposition tool, an exposure tool, a developer tool, an etch tool, a planarization tool, a plating tool, and/or another semiconductor processing tool may be used to perform various operations to form the metallization structures 122 and to form the interconnect structures 124 in the memory region 126 and the logic region 128 in the first portion of the interconnect layer 104 of the semiconductor device 100.

In some implementations, the first portion of the interconnect layer 104 may be formed in a plurality of layers. For example, an ILD layer 114 and an ESL 116 may be formed (e.g., using one or more deposition tools and/or one or more planarization tools), recesses may be formed in and/or through the ILD layer 114 and the ESL 116 (e.g., using an exposure tool, a developer tool, and/or an etch tool), and the layer 118a (e.g., the M0 layer) of metallization structures 122 may be formed in the ILD layer 114 and the ESL 116 (e.g., using one or more deposition tools and/or one or more planarization tools). Another ILD layer 114 and another ESL 116 may be formed, and the layer 120a (e.g., the V0 layer) of interconnect structures 124 may be formed in the ILD layer 114 and the ESL 116. The layers 118b-118g, and 120b-120f may be formed in a similar manner.

One or more deposition tools may be used to deposit the metallization structures 122 and/or the interconnect structures 124 using a PVD technique, an ALD technique, a CVD technique, an electroplating technique (e.g., an electro-chemical plating technique), and/or another suitable deposition technique. In some implementations, a planarization tool may be used to planarize the metallization structures 122 and/or the interconnect structures 124 after the metallization structures 122 and/or the interconnect structures 124 are deposited.

As shown in FIG. 2D, a second portion of the interconnect layer 104 of the semiconductor device 100 is formed above the first portion of the interconnect layer 104. The memory devices 132a and 132b and the bottom interconnect structures 140 of the semiconductor structure 130 are formed in the memory region 126 in the second portion of the interconnect layer 104. The second portion includes the layer 120e (e.g., the V4 layer) and the layer 118f (e.g., the M5 layer). The layers 120e and 118f are formed in the logic region 128 in an ILD layer 114 over the layer 120d (e.g., the V3 layer) and the layer 118e (e.g., the M4 layer). The layers 120e and 118f are formed in the logic region 128 after the memory devices 132a and 132b and the bottom interconnect structures 140 of the semiconductor structure 130 are formed in the memory region 126. The layers 120e and 118f in the logic region 128 may be formed in a similar manner to the layers 120a-120d, and the layers 118a-118e.

As shown in FIG. 2D, the layers 120e and 118f are formed in the logic region 128 on a lateral side of the memory devices 132a and 132b in the x-direction. The memory devices 132a and 132b are formed in the same ILD layer 114 as the layers 120e and 118f. The bottom electrode layer 134, the MTJ structure 136, and the top electrode layer 138 of each of the memory devices 132a-132c are formed over the bottom interconnect structures 140.

The memory devices 132a and 132b may be formed such that the bottom electrode layers 134 of the memory devices 132a and 132b land on the bottom interconnect structures 140 in the interconnect layer 104.

As shown in FIG. 2E, a remaining part of the second portion of the interconnect layer 104 of the semiconductor device 100 (e.g., layers 118g and 120f) is formed in the memory region 126 and in the logic region 128 above layers 118f and 120e and/or above the memory devices 132a and 132b. The layers 120f and 118g may be formed in a similar manner to the layers 120a-120e, and the layers 118a-118f. The interconnect structures 124 in layer 120f in the memory region 126 of the semiconductor device 100 are in direct contact with the top surfaces of the top electrode layers 138 of the memory devices 132a and 132b. Although not shown in FIGS. 2D and 2E, as shown in FIG. 1B, the semiconductor structure 130′ may be formed in a similar arrangement to that of the semiconductor structure 130 in the semiconductor device 100.

As indicated above, FIGS. 2A-2E are provided as an example. Other examples may differ from what is described with regard to FIGS. 2A-2E.

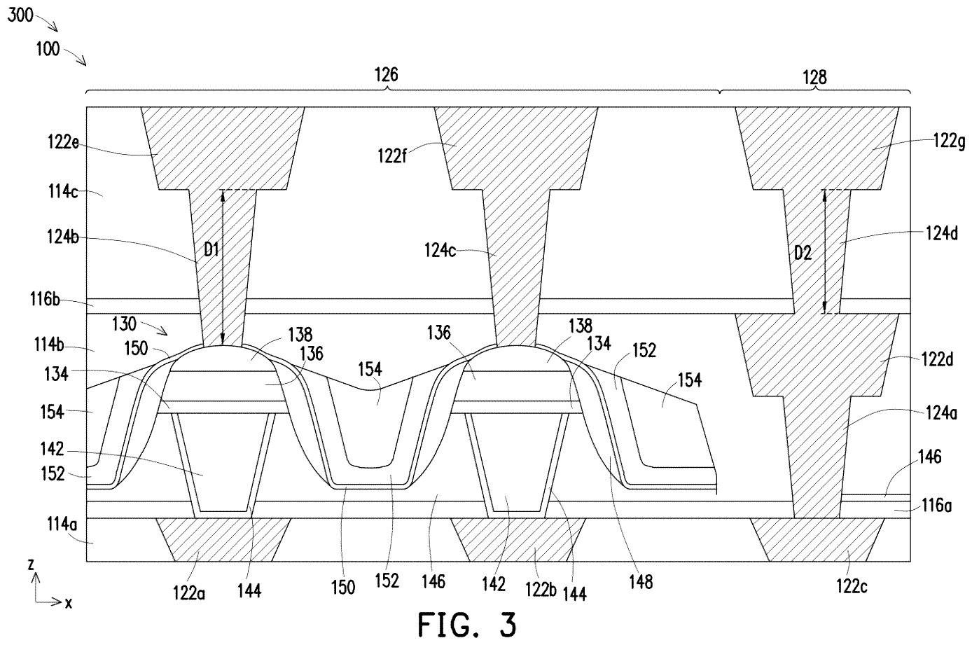

FIG. 3 is a diagram of an example implementation 300 of a portion of the semiconductor device 100 including the semiconductor structure 130. As shown in FIG. 3, the semiconductor device is divided into a memory region 126 and a logic region 128. The semiconductor device 100 includes ILD layers 114a, 114b, and 114c, and ESLs 116a and 116b. The semiconductor device 100 further includes metallization structures 122a, 122b, and 122c in ILD layer 114a, metallization structure 122d in ILD layer 114b, and metallization structures 122e, 122f, and 122g in ILD layer 114c. Metallization structures in the same ILD layer may be in the same metallization layer (e.g., one of layers 118a-g), and may have top surfaces that are coplanar with each other.

An interconnect structure 124a is disposed between and connects metallization structures 122c and 122d. An interconnect structure 124d is disposed between and connects metallization structures 122d and 122g. The interconnect structure 124a is disposed through part of ILD layer 114b, through part of the dielectric layer 146, and through ESL 116a to land on the metallization layer 122c. The interconnect structure 124d is disposed through part of ILD layer 114c and through ESL 116b to land on metallization structure 122d. An interconnect structure 124b is disposed between and connects a top electrode layer 138 of a memory device 132a and metallization structure 122e. An interconnect structure 124c is disposed between and connects a top electrode layer 138 of a memory device 132b and metallization structure 122f. The interconnect structures 124b and 124c are disposed through part of ILD layer 114c, through ESL 116b, through part of ILD layer 114b, and through portions of the second spacer layer 150 on top surfaces of the top electrode layers 138. The interconnect structures 124b and 124c respectively land on a top surface of the top electrode layer 138 of the memory device 132a and the memory device 132b.

The bottom interconnect structures 140 of the semiconductor structure 130 respectively land on the metallization structures 122a and 122b to connect respective bottom electrode layers 134 to the respective metallization structures 122a and 122b. Each bottom interconnect structure 140 is formed in a portion of the dielectric layer 146, through a bottom surface of the dielectric layer 146, and through the ESL 116a. The ILD layer 114b fills in areas over and on sides of the semiconductor structure 130.

In some implementations, a vertical dimension D1 (e.g., z-direction dimension) (e.g., height or depth) of each interconnect structure 124b and 124c may be greater than a vertical dimension D2 (e.g., z-direction dimension) of the interconnect structure 124d. The greater vertical dimension D1 may be due to a top surface of the top electrode layer 138 of each of the memory devices 132a and 132b failing to reach a top surface of the ILD layer 114b and/or a bottom surface of the ESL 116b. As a result, the interconnect structures 124b and 124c may be formed through a top portion of the ILD layer 114b to land on the top electrode layer 138 of each of the memory devices 132a and 132b. In some implementations, the vertical dimension D1 of the interconnect structures 124a and 124b may be approximately 100 angstroms to approximately 300 angstroms greater than the vertical dimension D2 of the interconnect structure 124d. Alternatively, the vertical dimension D1 of each of the interconnect structures 124b and 124c may be equal to the vertical dimension D2 of the interconnect structure 124d. In the case where the vertical dimensions D1 and D2 are equal, the top surfaces of the top electrode layer 138 of each of the memory devices 132a and 132b may be co-planar with or approximately co-planar with the top surface of the metallization structure 122d. If the top surfaces of the top electrode layer 138 of each of the memory devices 132a and 132b are co-planar with or approximately co-planar with the top surface of the metallization structure 122d, the vertical (e.g., z-direction dimension of the bottom interconnect structures 140 may be larger than if the top surface of the top electrode layer 138 of each of the memory devices 132a and 132b fails to reach a top surface of the ILD layer 114b and/or a bottom surface of the ESL 116b.

The metallization structures 122e and 122f are respectively connected to the top electrode layer 138 of each memory device 132a and 132b through the interconnect structures 124b and 124c. The interconnect structures 124b and 124c are in direct contact with a surface of the top electrode layer 138 of memory devices 132a and 132b, respectively. In some implementations, the surface of the top electrode layer 138 of each memory device 132a and 132b with which the interconnect structures 124b and 124c are in direct contact is curved. Top surfaces of the metallization structures 122e and 122f may be co-planar with or approximately co-planar with a top surface of the metallization structure 122g.

As indicated above, FIG. 3 is provided as an example. Other examples may differ from what is described with regard to FIG. 3.

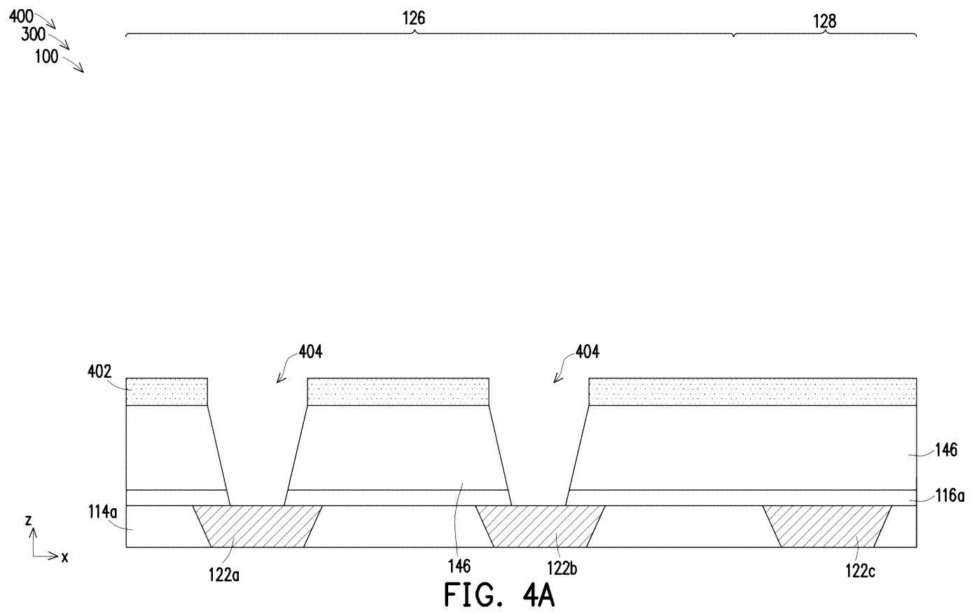

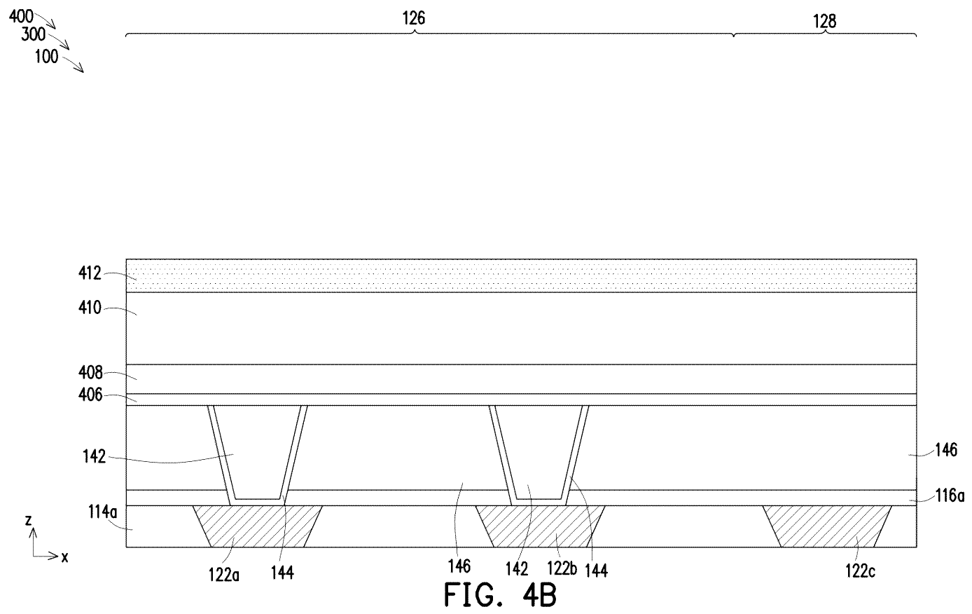

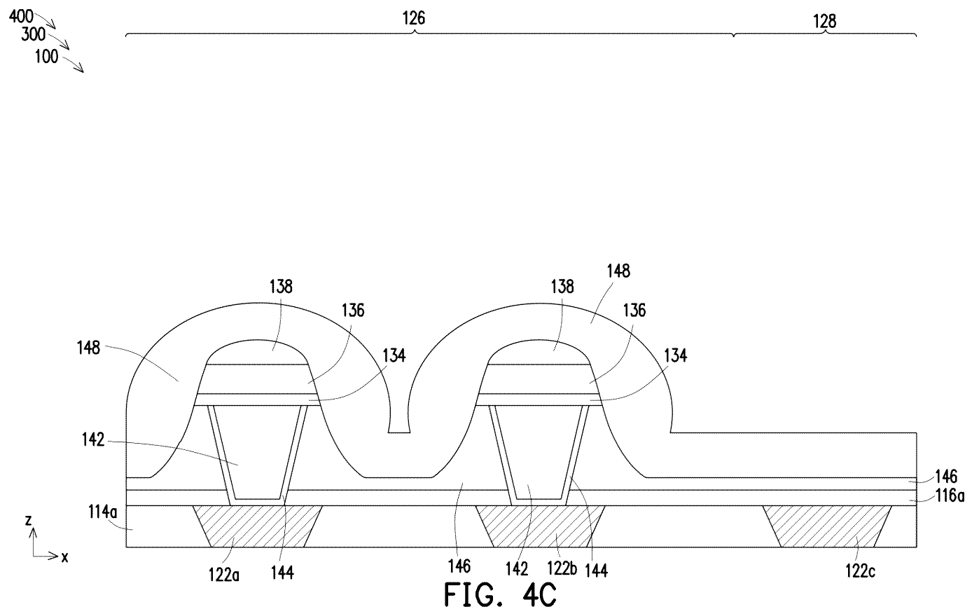

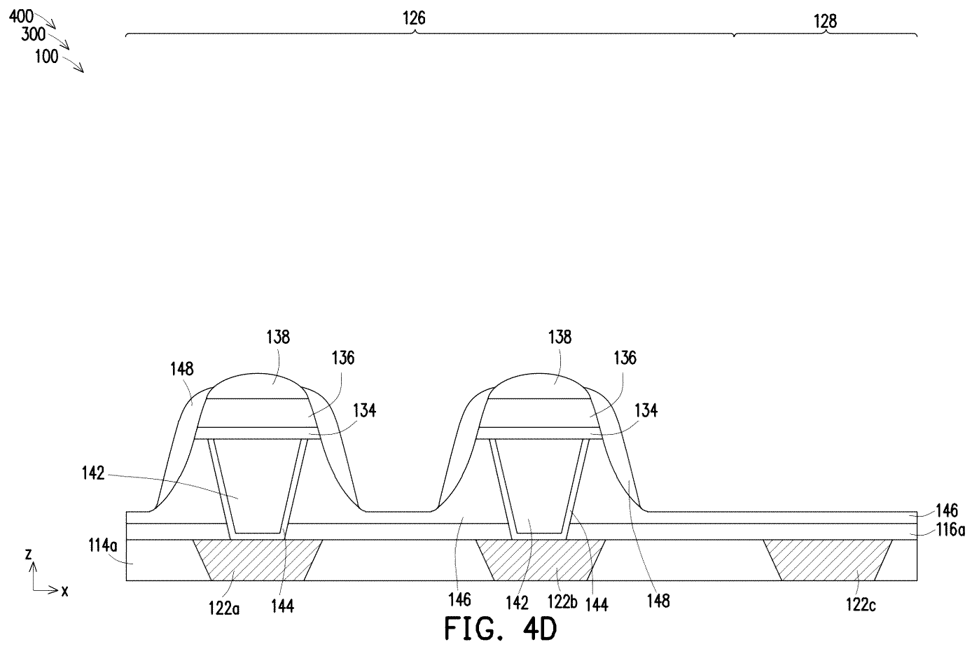

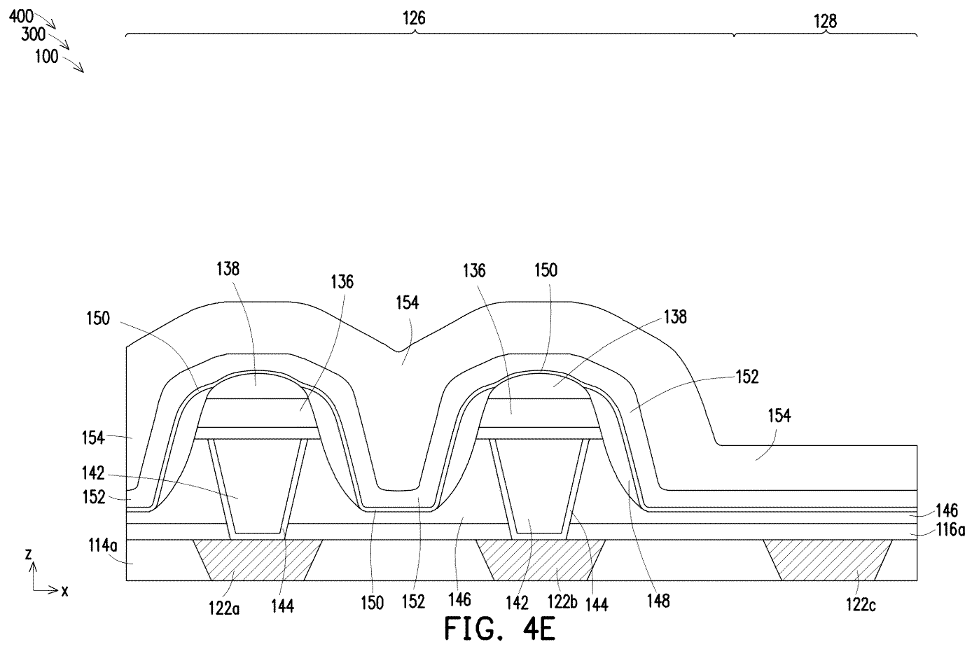

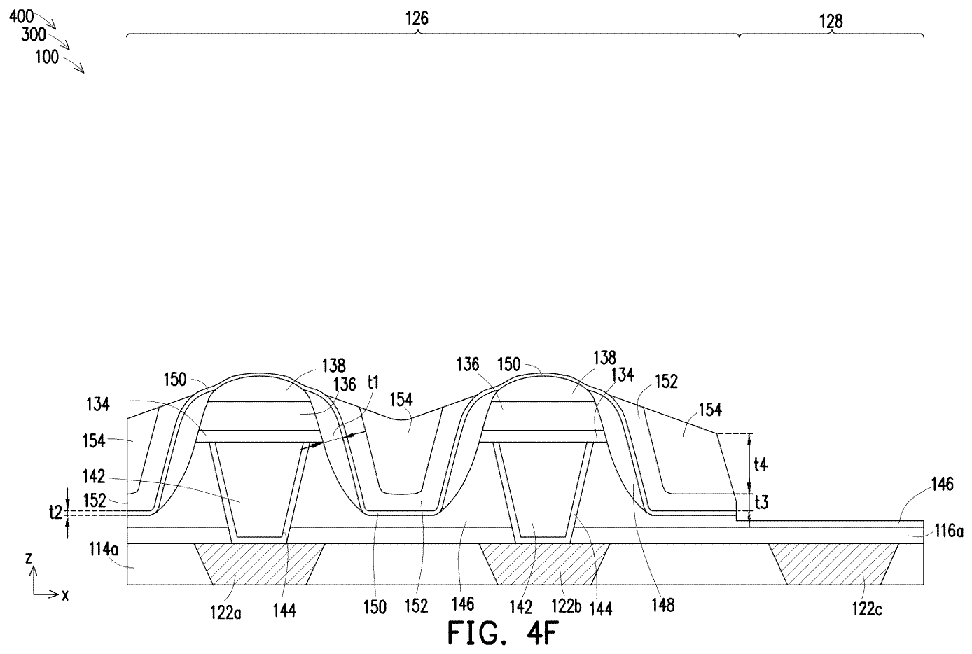

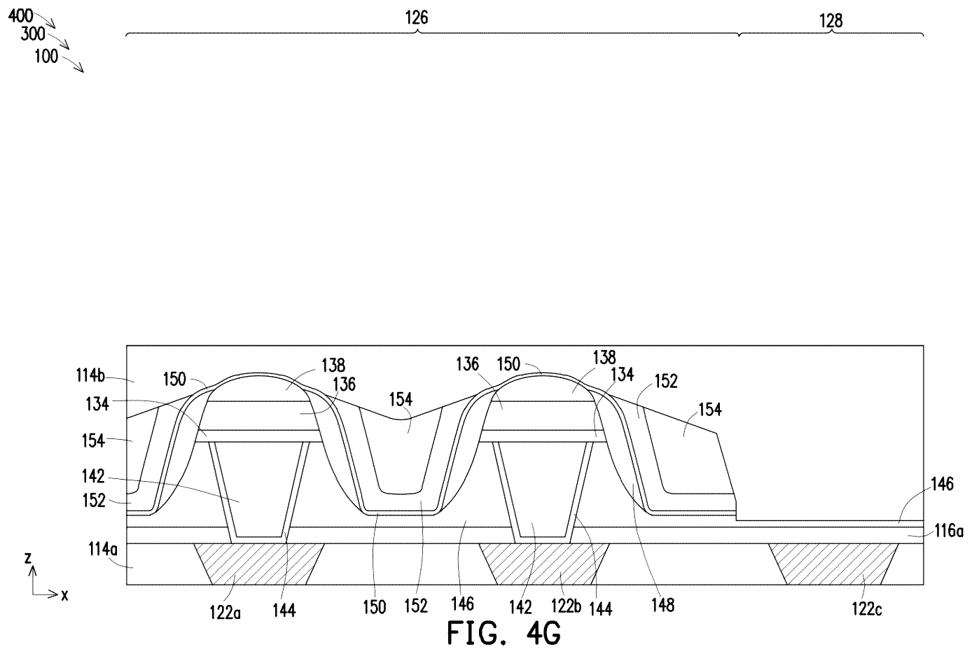

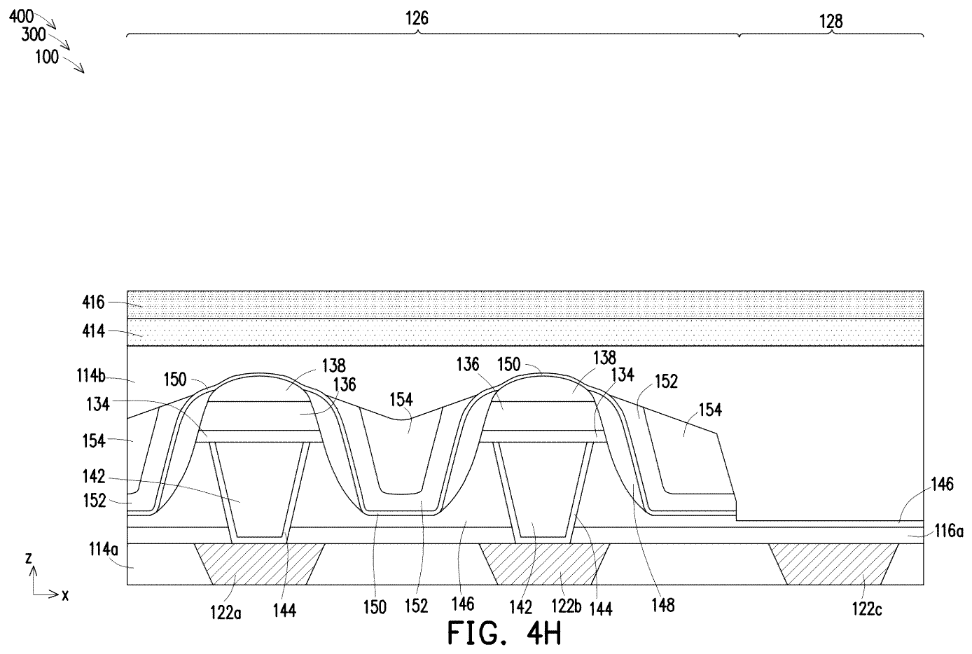

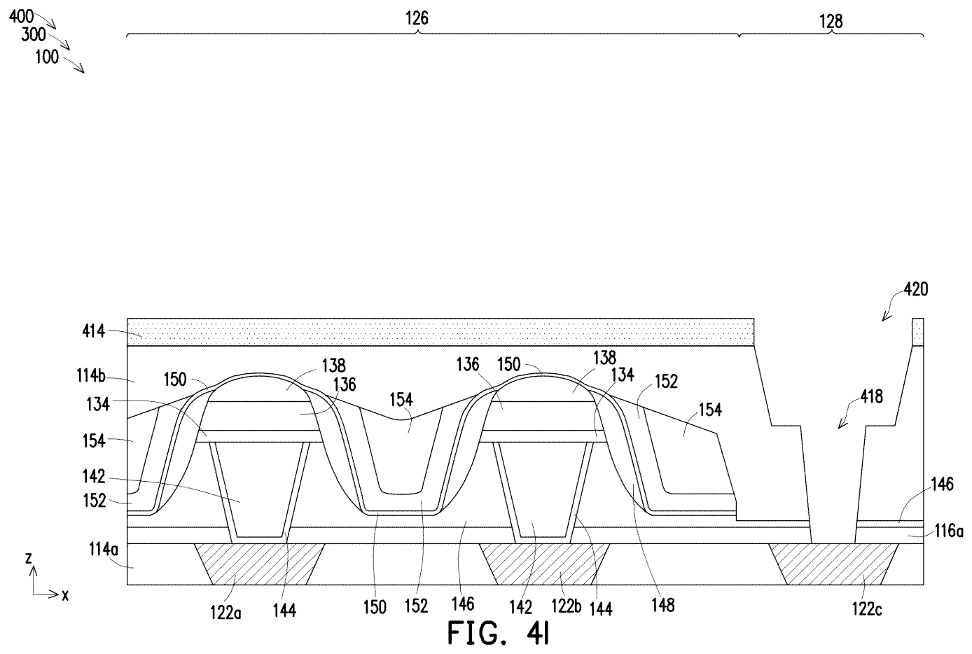

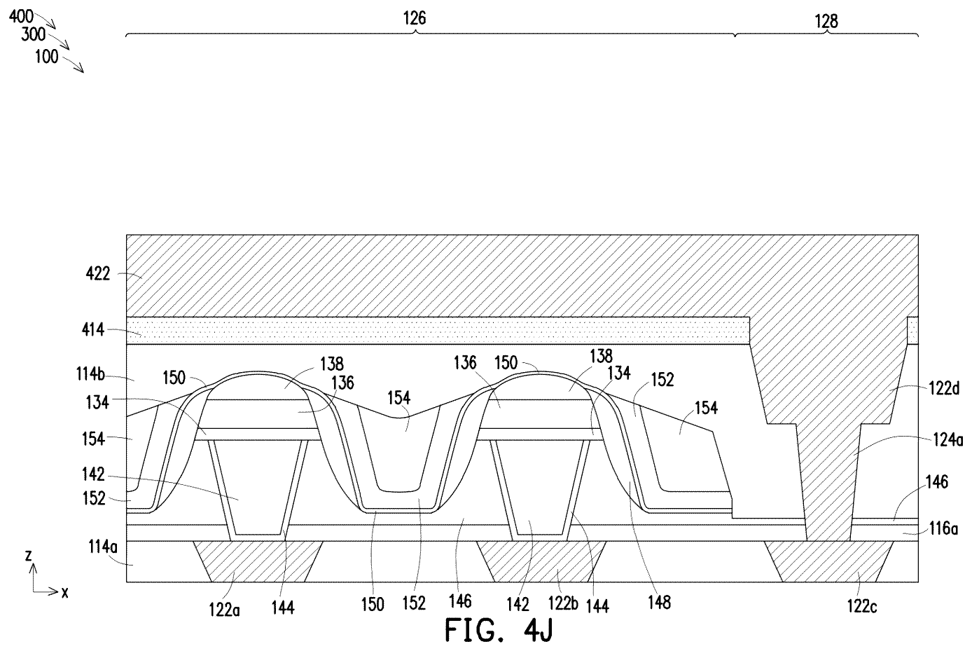

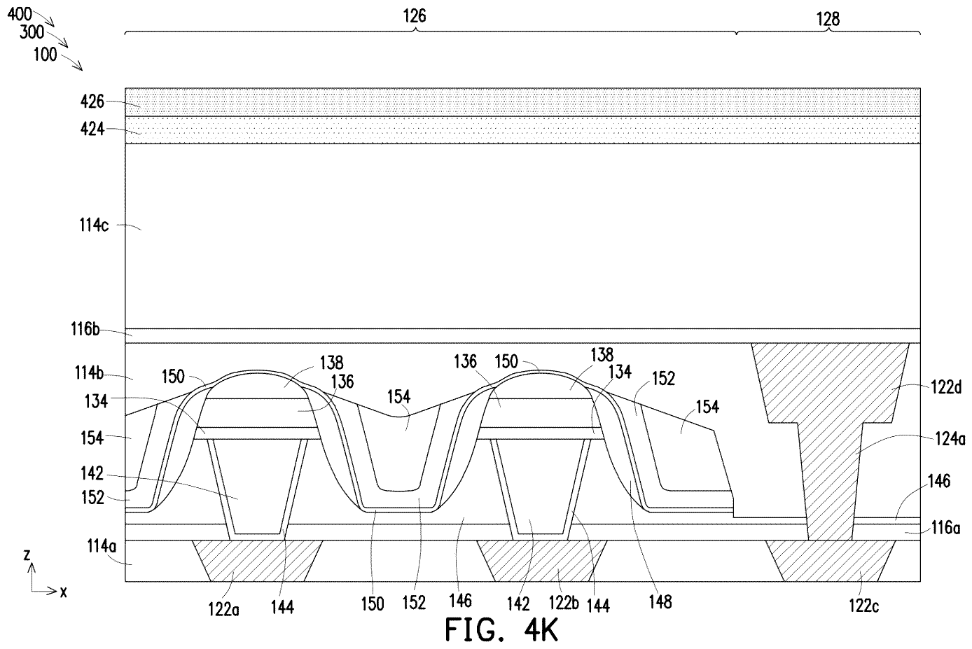

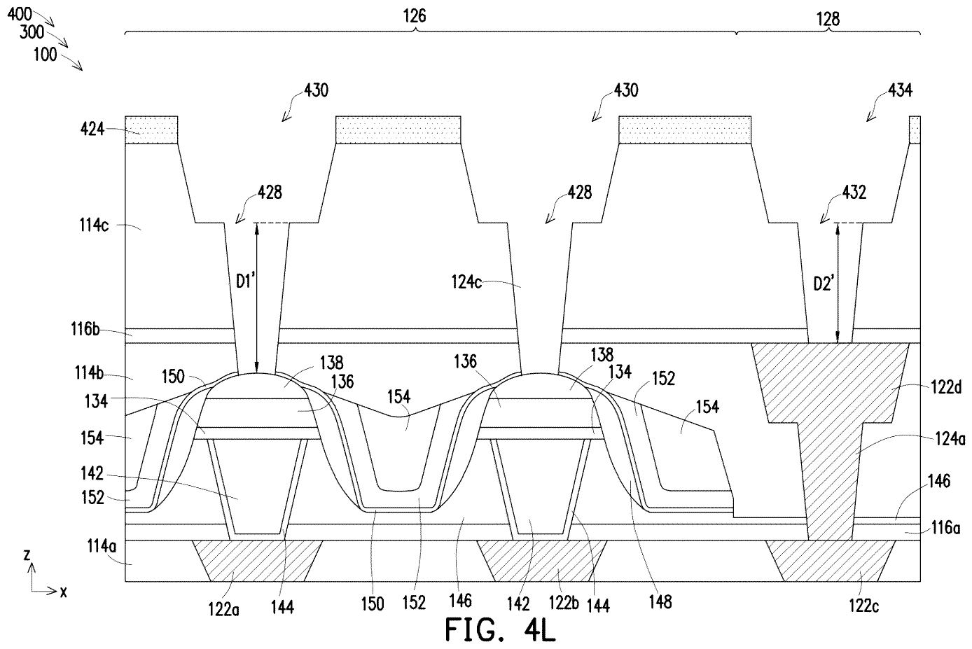

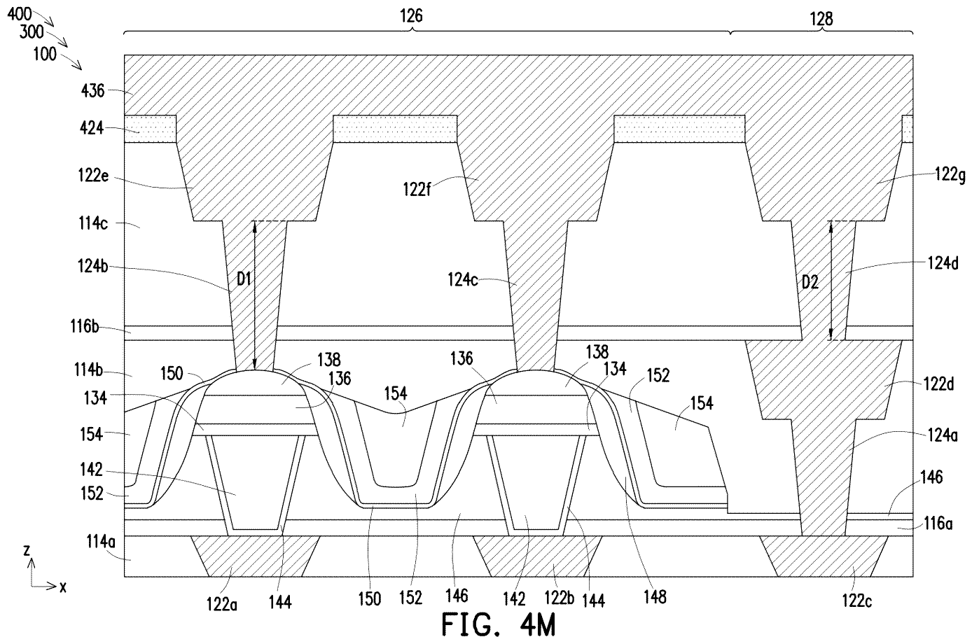

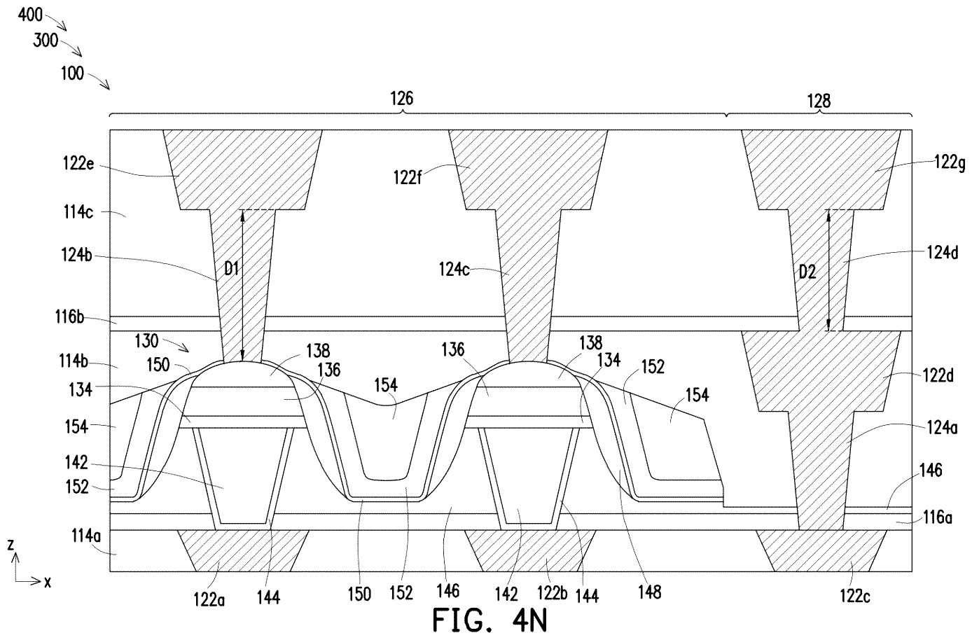

FIGS. 4A-4N are diagrams of an example implementation 400 of forming a portion of a semiconductor device 100 including the semiconductor structure 130 described herein. In some implementations, one or more of the semiconductor processing operations described in connection with FIGS. 4A-4N may be performed using one or more semiconductor processing tools, such as a deposition tool, an exposure tool, a developer tool, an etch tool, a planarization tool, a wafer/die transport tool, and/or another type of semiconductor processing tool. In some implementations, one or more of the semiconductor processing operations described in connection with FIGS. 4A-4N may be performed as part of the process for forming the semiconductor device 100 described in connection with FIGS. 2A-2E.

As shown in FIG. 4A, the ESL 116a and the dielectric layer 146 are formed on the layer 118e (e.g., the M4 layer) including the metallization structures 122a and 122b in the memory region 126, and the metallization structure 122c in the logic region 128. The ESL 116a is formed over the ILD layer 114a, and the dielectric layer 146 is formed on the ESL 116a in the memory region 126 and in the logic region 128. The ESL 116a and the dielectric layer 146 may be deposited using a PVD technique, an ALD technique, a CVD technique, an oxidation technique, and/or another suitable deposition technique. In some implementations, a planarization tool may be used to planarize the ESL 116a and/or the dielectric layer 146 after the ESL 116a and/or the dielectric layer 146 are deposited.

A masking layer may be formed on the dielectric layer 146 in the interconnect layer 104 of the semiconductor device 100. For example, a dielectric masking layer 402 may be formed on the dielectric layer 146. The dielectric masking layer 402 may include a silicon oxynitride material (SiON) and/or another suitable dielectric material.

A deposition tool may be used to deposit the dielectric masking layer 402 using a PVD technique, an ALD technique, a CVD technique, an oxidation technique, and/or another suitable deposition technique. In some implementations, a planarization tool is used to perform a planarization operation (e.g., a CMP operation) to planarize the dielectric masking layer 402 after the dielectric masking layer 402 is deposited.

A photoresist layer may be formed above the dielectric masking layer 402, and a pattern may be formed in the photoresist layer. A deposition tool may be used to form the photoresist layer on the dielectric masking layer 402 (e.g., using a spin-coating technique or another suitable deposition technique). In some implementations, a bottom antireflective coating (BARC) is first deposited on the dielectric masking layer 402, and then the photoresist layer is deposited onto the BARC. An exposure tool may be used to expose the photoresist layer to a radiation source to pattern the photoresist layer. A developer tool may be used to develop and remove portions of the photoresist layer to expose the pattern.

An etch tool may be used to etch the dielectric masking layer 402 based on the pattern in the photoresist layer, to transfer the pattern to the dielectric masking layer 402. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). The etchant may have a higher etch rate for the dielectric masking layer 402 compared to the material of the underlying dielectric layer 146. Thus, the etch operation may stop on the dielectric layer 146 with minimal etching to the dielectric layer 146.

As further shown in FIG. 4A, another etch operation is performed to etch through the dielectric layer 146 and through the ESL 116a to form recesses 404. The etch operation may include, for example, a gas-based etch operation in which a different type of etchant is used, as compared to the etchant that was used to transfer the pattern to the dielectric masking layer 402. Thus, the semiconductor device 100 may be transferred from a first etch tool (in which the pattern was transferred to the dielectric masking layer 402) to a second etch tool (in which the dielectric layer 146 and the ESL 116a are etched) using a wafer/die transport tool to reduce the likelihood of cross-contamination between the first and second etch tools. Alternatively, an etch tool that has multiple processing chambers (e.g., a cluster tool) may be used, and the semiconductor device 100 may be transferred between processing chambers of the etch tool for etching using different types of etchants.

The gas-based etchant that is used to etch the dielectric layer 146 and the ESL 116a, may include a fluorine-based gas etchant that has a higher etch rate for the dielectric materials of the dielectric layer 146 and the ESL 116a compared to the etch rate of the dielectric masking layer 402. This enables the dielectric layer 146 and the ESL 116a to be etched with minimal etching to the dielectric masking layer 402. The fluorine-based etchant may include a carbon fluoride-based (CFₓ) gas etchant such as a carbon tetrafluoride (CF₄) gas etchant.

In some implementations, a plurality of etch operations (e.g., a plurality of gas-based etch operations using the fluorine-based etchant) are performed to form the recesses 404. For example, a first etch operation (referred to as a “main etch” operation) may be performed to form the recesses 404 to the ESL 116a. In other words, etching in the first etch operation stops at the ESL 116a such that the ESL 116a remains between the bottom of the recesses 404 and the underlying metallization structures 122a and 122b. The ESL 116a is kept over the metallization structures 122a and 122b to prevent the metallization structures 122a and 122b from being exposed to oxygen and other contaminants that might otherwise result in oxidation of the metallization structures 122a and 122b.

A second etch operation (referred to as a “linear removal” etch operation) may be performed to etch through the ESL 116a at the bottom of the recesses 404 to extend the recesses 404 through the ESL 116a and to the underlying metallization structures 122a and 122b. Thus, the metallization structures 122a and 122b are exposed through the recesses 404 after the third etch operation. The second etch operation may be performed using the second etch tool and using a fluorine-based etchant such as a carbon fluoride-based (CFₓ such as CF₄) gas etchant. The dielectric masking layer 402 remains on the dielectric layer 146 during the second etch operation to etch through the ESL 116a such that the dielectric masking layer 402 protects the dielectric layer 146 from being etched, which reduces the likelihood of critical dimension reduction. Following exposure of the metallization structures 122a and 122b in the recesses 404, the dielectric masking layer 402 may be removed from the dielectric layer 146.

As shown in FIG. 4B, the liner layer 144 may be deposited on the sidewalls and on the bottom surfaces of the recesses 404. The bottom surfaces of the recesses 404 correspond to the top surfaces of the metallization structures 122a and 122b, and thus the liner layer 144 may be in physical contact with the top surfaces of the metallization structures 122a and 122b. The liner layer 144 may also be deposited on the top surface of the dielectric layer 146 between adjacent recesses 404, and removed from the top surface of the dielectric layer 146 in a subsequent CMP operation. In some implementations, a deposition tool is used to conformally deposit the liner layer 144 such that the liner layer 144 conforms to the profile of the recesses 404. In some implementations, a conformal CVD technique and/or an ALD technique is used to deposit the liner layer 144.

The fill layer 142 may be deposited on the liner layer 144. The fill layer 142 may be deposited such that the fill layer 142 fills the remaining areas of the recesses 404. The fill layer 142 may also be deposited on the top surface of the liner layer 144 between recesses 404, and removed along with the liner layer 144 from the top surface of the dielectric layer 146 in a subsequent CMP operation. In some implementations, a deposition tool is used to deposit the fill layer 142 using a PVD technique, a CVD technique, an ALD technique, and/or another suitable deposition technique to form the bottom interconnect structures 140 including the fill layers 142 and the liner layers 144.

As further shown in FIG. 4B, in some implementations, a blanket bottom electrode layer 406 is deposited on the bottom interconnect structures 140 and on portions of the dielectric layer 146 in which the bottom interconnect structures 140 may be formed. A deposition tool may be used to deposit the blanket bottom electrode layer 406 using a CVD technique, a PVD technique, an ALD technique, an electroplating technique, and/or another suitable deposition technique. The material of the blanket bottom electrode layer 406 may be deposited in one or more deposition operations. In some implementations, a seed layer is first deposited, and the material of the blanket bottom electrode layer 406 is deposited on the seed layer. In some implementations, a planarization tool is used to perform a planarization operation (e.g., a CMP operation) to planarize the blanket bottom electrode layer 406 after the blanket bottom electrode layer 406 is deposited. The blanket bottom electrode layer 406 may include one or more electrically conductive materials to be used for the bottom electrode layers 134. Examples include metals such as molybdenum (Mo), nickel (Ni), iridium (Ir), and chromium (Cr), as well as metal nitrides such as titanium nitride (TiN) or tantalum nitride (TaN), among other examples.

A deposition tool may form a blanket MTJ structure 408 over and/or on the top surface of the blanket bottom electrode layer 406. In some implementations, a deposition tool forms the blanket MTJ structure 408 using a spin-coating technique, a CVD technique, a PVD technique, an ALD technique, and/or another deposition technique. In some implementations, a planarization tool is used to perform a planarization operation (e.g., a CMP operation) to planarize the blanket MTJ structure 408 after the blanket MTJ structure 408 is deposited. The blanket MTJ structure 408 may include ferromagnetic layers separated by a tunnel barrier layer. The ferromagnetic layers may include ferrous materials including a combination of iron (Fe) and one or more of cobalt (Co), boron (B), and/or nickel (Ni), among other examples, and the tunnel barrier layer may include a crystalline material, such as magnesium oxide (MgO) and/or another suitable material.

A deposition tool may form a mask structure, including a top electrode mask layer 410 and a dielectric mask layer 412 on the top electrode mask layer 410, over and/or on the top surface of the blanket MTJ structure 408. In some implementations, a deposition tool forms the mask structure, including a top electrode mask layer 410 and a dielectric mask layer 412, using a spin-coating technique, a CVD technique, a PVD technique, an ALD technique, and/or another deposition technique. The top electrode mask layer 410 may include one or more electrically conductive materials to be used for the top electrode layers 138. Examples include metals such as molybdenum (Mo), nickel (Ni), iridium (Ir), and chromium (Cr), as well as metal nitrides such as titanium nitride (TiN) or tantalum nitride (TaN), among other examples. In some implementations, the dielectric mask layer 412 includes tetraethyl orthosilicate (TEOS), an oxide, or another suitable dielectric material. In some implementations, the mask structure may be patterned in an etching operation to form a plurality of mask structure portions spaced apart from each other in the x-direction on the blanket MTJ structure 408. Each mask structure portion includes a portion of the top electrode mask layer 410 and a portion of the dielectric mask layer 412 on the portion of the top electrode mask layer 410.

As shown in FIG. 4C, portions of the blanket MTJ structure 408 and the blanket bottom electrode layer 406 are removed in one or more etching processes, where the plurality of mask structure portions, each including a portion of the top electrode mask layer 410 and a portion of the dielectric mask layer 412 on the portion of the top electrode mask layer 410, are used as masks that cover portions of the blanket MTJ structure 408 and underlying portions of the blanket bottom electrode layer 406. Exposed portions of the blanket MTJ structure 408 and of the blanket bottom electrode layer 406 that are not covered by the plurality of mask structure portions are removed in the one or more etching processes to pattern the blanket MTJ structure 408 into the MTJ structures 136 and to pattern the blanket bottom electrode layer 406 into the bottom electrode layers 134. In addition, the one or more etching processes result in removal of the portions of the dielectric mask layers 412, and patterning of the remaining portions of the top electrode mask layers 410 into the top electrode layers 138, where each top electrode layer 138 may have a curved top surface. In some implementations, an etch tool uses a wet etch technique, a dry etch technique, a plasma-enhanced etch technique, and/or another type of etch technique to perform the one or more etching processes.

The resulting patterned MTJ structures 136 and patterned bottom electrode layers 134 each include angled side surfaces, such that the MTJ structures 136 and bottom electrode layers 134 each taper to a larger width (e.g., x-direction dimension) in the downward z-direction. The one or more etching processes cause removal of portions of the dielectric layer 146 between and/or adjacent to the memory devices 132a and 132b to result in a curved profile of the top surfaces of the portions of the dielectric layer 146 between and/or adjacent to the memory devices 132a and 132b.

As further shown in FIG. 4C, a first spacer layer 148 is conformally deposited on exposed side surfaces of the bottom electrode layers 134, on exposed side surfaces of the MTJ structures 136, on exposed side and top surfaces of the top electrode layers 138, and on the exposed surfaces of the dielectric layer 146 between and/or adjacent to the memory devices 132a and 132b. The first spacer layer 148 is deposited on the exposed surfaces of the dielectric layer 146 in the memory region 126 and in the logic region 128. A deposition tool may be used to deposit the first spacer layer 148 using an ALD technique, a CVD technique, and/or another suitable deposition technique.

As shown in FIG. 4D, an etch tool performs an etch process to remove portions of the first spacer layer 148 from the top surfaces of top electrode layers 138. Portions of the first spacer layer 148 are further removed from some surfaces (e.g., surfaces extending in the horizontal direction (x-direction)) of the dielectric layer 146 between and/or adjacent to the memory devices 132a and 132b and on the side of the semiconductor structure 130 (e.g., at an end of the memory region 126 and in the logic region 128). In some implementations, the etch operation includes a dry etch operation (e.g., a plasma-based etch operation, a gas-based etch operation), a wet chemical etch operation, and/or another type of etch operation.

As shown in FIG. 4E, a stacked arrangement of the second spacer layer 150, the third spacer layer 152, and the fourth spacer layer 154 is conformally deposited on the top surfaces of the top electrode layers 138, on the remaining portions of the first spacer layer 148 (which may be referred to herein as first spacer layers 148), and on exposed surfaces of the dielectric layer 146. In more detail, the second spacer layer 150 (e.g., capping spacer layer) is conformally deposited on exposed surfaces of the remaining portions of the first spacer layer 148, on exposed top surfaces of the top electrode layers 138, and on the exposed surfaces of the portions of the dielectric layer 146 between and/or adjacent to the memory devices 132a and 132b where the first spacer layer 148 was removed. The second spacer layer 150 is deposited on surfaces of the dielectric layer 146 in the memory region 126 and in the logic region 128. A deposition tool may be used to deposit the second spacer layer 150 using an ALD technique, a CVD technique, and/or another suitable deposition technique.

The third spacer layer 152 is conformally deposited on exposed surfaces of the second spacer layer 150. A deposition tool may be used to deposit the third spacer layer 152 using an ALD technique, a CVD technique, and/or another suitable deposition technique. The fourth spacer layer 154 is conformally deposited on exposed surfaces of the third spacer layer 152. A deposition tool may be used to deposit the fourth spacer layer 154 using an ALD technique, a CVD technique, and/or another suitable deposition technique.

As shown in FIG. 4F, an etch tool performs one or more etch operations to remove portions of the third spacer layer 152 and the fourth spacer layer 154 from surfaces of portions of the second spacer layer 150 on the first spacer layers 148, and on top surfaces of the top electrode layers 138. Portions of the second spacer layer 150, the third spacer layer 152, and the fourth spacer layer 154 are further removed from part of the dielectric layer 146 on the side of the semiconductor structure 130 (e.g., at an end of the memory region 126 and in the logic region 128). In some implementations, the one or more etch operations include a dry etch operation (e.g., a plasma-based etch operation, a gas-based etch operation), a wet chemical etch operation, and/or another type of etch operation. Following the one or more etch operations, a thickness t2 of the second spacer layer 150 may be smaller than thicknesses t1, t3, and t4 of the first spacer layers 148, the third spacer layers 152, and the fourth spacer layers 154, respectively.

As shown in FIG. 4G, the ILD layer 114b is deposited over the memory devices 132a and 132b in the memory region 126, including on the exposed surfaces of the second spacer layer 150, on exposed surfaces of the third and fourth spacer layers 152 and 154. The ILD layer 114b is further deposited on the dielectric layer 146 on the side of the semiconductor structure 130 (e.g., at an end of the memory region 126 and in the logic region 128). A deposition tool may be used to deposit the ILD layer 114b using a PVD technique, an ALD technique, a CVD technique, an oxidation technique, and/or another suitable deposition technique. A planarization tool may be used to perform a planarization operation (e.g., a CMP operation) to planarize the ILD layer 114b.

As shown in FIG. 4H, following deposition and/or planarization of the ILD layer 114b, a dielectric masking layer 414 is deposited on top surfaces of the ILD layer 114b. A deposition tool may be used to deposit the dielectric masking layer 414 using a PVD technique, an ALD technique, a CVD technique, an oxidation technique, and/or another suitable deposition technique.

A photoresist layer 416 may be formed above the dielectric masking layer 414, and a pattern may be formed in the photoresist layer. A deposition tool may be used to form the photoresist layer on the dielectric masking layer 414 (e.g., using a spin-coating technique or another suitable deposition technique). In some implementations, a BARC is first deposited on the dielectric masking layer 414, and then the photoresist layer is deposited onto the BARC. An exposure tool may be used to expose the photoresist layer to a radiation source to pattern the photoresist layer. A developer tool may be used to develop and remove portions of the photoresist layer to expose the pattern.

An etch tool may be used to etch the dielectric masking layer 414 based on the pattern in the photoresist layer, to transfer the pattern to the dielectric masking layer 414. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). The etchant may have a higher etch rate for the dielectric masking layer 414 compared to the material of the underlying ILD layer 114b. Thus, the etch operation may stop on the ILD layer 114b, with minimal etching to the ILD layer 114b.

As shown in FIG. 4I, one or more additional etch operations may be performed to etch through the ILD layer 114b, the dielectric layer 146, and the ESL 116a to form recesses 418 and 420 in the logic region 128, where bottom surface of the recess 418 exposes portions of top surfaces of the underlying metallization structure 122c. The etch operations may include, for example, a gas-based etch operation in which a different type of etchant is used, as compared to the etchant that was used to transfer the pattern to the dielectric masking layer 414. Thus, the semiconductor device 100 may be transferred from a first etch tool (in which the pattern was transferred to the dielectric masking layer 414) to a second etch tool (in which the ILD layer 114b, the dielectric layer 146, and the ESL 116a are etched) using a wafer/die transport tool to reduce the likelihood of cross-contamination between the first and second etch tools. Alternatively, an etch tool that has multiple processing chambers (e.g., a cluster tool) may be used, and the semiconductor device 100 may be transferred between processing chambers of the etch tool for etching using different types of etchants.

In some implementations, a dual damascene process is used to form the recesses 418 and 420. For example, the recess 418 may be formed in and/or through a bottom portion of the ILD layer 114b, the dielectric layer 146, and ESL 116a. The recess 420 may be formed in the top portion of the ILD layer 114b above the recess 420.

An interconnect structure-first dual damascene procedure can be performed in which the recesses 418 and 420 are formed by forming the recess 418 before forming the recess 420. In some implementations, a trench-first dual damascene procedure can be performed in which the recesses 418 and 420 are formed by forming the recess 420 before forming the recess 418.

As shown in FIG. 4J, one or more deposition tools may be used to deposit conductive material 422 in the recesses 418 and 420 to form the metallization structure 122d and the interconnect structure 124a, using a PVD technique, an ALD technique, a CVD technique, an electroplating technique (e.g., an electro-chemical plating technique), and/or another suitable deposition technique. As noted herein, the conductive material to form the metallization structure 122d and the interconnect structure 124a may include, for example, tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included in the metallization structure 122d and the interconnect structure 124a. The one or more liner layers may include barrier liners, adhesion liners, and/or another type of liners. Examples of materials for the one or more liners include tantalum nitride (TaN) and/or titanium nitride (TiN), among other examples.

As shown in FIG. 4K, a planarization tool may be used to planarize the surface of the ILD layer 114b to remove the dielectric masking layer 414 and excess portions of the conductive material 422 formed on the dielectric masking layer 414 and/or over the top surfaces of the ILD layer 114b. Another ESL 116b is deposited over the ILD layer 114b. A deposition tool may be used to deposit the ESL 116b using a PVD technique, an ALD technique, a CVD technique, an oxidation technique, and/or another suitable deposition technique.

The ILD layer 114c is deposited on the ESL 116b. A deposition tool may be used to deposit the ILD layer 114c using a PVD technique, an ALD technique, a CVD technique, an oxidation technique, and/or another suitable deposition technique. A dielectric masking layer 424 is deposited on top surfaces of the ILD layer 114c. A deposition tool may be used to deposit the dielectric masking layer 424 using a PVD technique, an ALD technique, a CVD technique, an oxidation technique, and/or another suitable deposition technique.

A photoresist layer 426 may be formed above the dielectric masking layer 424, and a pattern may be formed in the photoresist layer. A deposition tool may be used to form the photoresist layer on the dielectric masking layer 424 (e.g., using a spin-coating technique or another suitable deposition technique). In some implementations, a BARC is first deposited on the dielectric masking layer 424, and then the photoresist layer is deposited onto the BARC. An exposure tool may be used to expose the photoresist layer to a radiation source to pattern the photoresist layer. A developer tool may be used to develop and remove portions of the photoresist layer to expose the pattern.

An etch tool may be used to etch the dielectric masking layer 424 based on the pattern in the photoresist layer, to transfer the pattern to the dielectric masking layer 424. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). The etchant may have a higher etch rate for the dielectric masking layer 424 compared to the material of the underlying ILD layer 114c. Thus, the etch operation may stop on the ILD layer 114c, with minimal etching to the ILD layer 114c.

As shown in FIG. 4L, one or more additional etch operations may be performed to etch through the ILD layer 114c, the ESL 116b, the ILD layer 114b, and the second spacer layer 150 to form recesses 428 and 430 in the memory region 126, and to etch through the ILD layer 114c and the ESL 116b to form recesses 432 and 434 in the logic region 128. Bottom surfaces of the recesses 428 expose portions of top surfaces of the underlying top electrode layers 138 of the memory devices 132a and 132b, and a bottom surface of the recess 432 exposes a portion of the top surface of the underlying metallization structure 122d. In some implementations, the recesses 428 and 432 are simultaneously formed during the same etch operation, and the recesses 430 and 434 are simultaneously formed during the same etch operation. The same mask structure (e.g., dielectric masking layer 424 and photoresist layer 426) is used to form the recesses 428, 430, 432, and 434.

The etch operations may include, for example, a gas-based etch operation in which a different type of etchant is used, as compared to the etchant that was used to transfer the pattern to the dielectric masking layer 424. Thus, the semiconductor device 100 may be transferred from a first etch tool (in which the pattern was transferred to the dielectric masking layer 424) to a second etch tool (in which the ILD layer 114c, the ESL 116b, the ILD layer 114b, and the second spacer layer 150 are etched) using a wafer/die transport tool to reduce the likelihood of cross-contamination between the first and second etch tools. Alternatively, an etch tool that has multiple processing chambers (e.g., a cluster tool) may be used, and the semiconductor device 100 may be transferred between processing chambers of the etch tool for etching using different types of etchants.

In some implementations, a dual damascene process is used to form the recesses 428, 430, 432, and 434. For example, the recesses 428 may be formed in and/or through a bottom portion of the ILD layer 114c, through the ESL 116b, through a top portion of the ILD layer 114b, and through the second spacer layer 150. The recess 432 may be formed in and/or through a bottom portion of the ILD layer 114c and through the ESL 116b. The recesses 430 and 432 may be formed in the top portion of the ILD layer 114c above the recesses 428 and 432, respectively.

An interconnect structure-first dual damascene procedure can be performed in which the recesses 428, 430, 432, and 434 are formed by forming the recesses 428 and 432 before forming the recesses 430 and 434. In some implementations, a trench-first dual damascene procedure can be performed in which the recesses 428, 430, 432, and 434 are formed by forming the recesses 430 and 434 before forming the recesses 428 and 432.

In some implementations, a vertical dimension D1′ (e.g., z-direction dimension) (e.g., height or depth) of each recess 428 may be greater than a vertical dimension D2′ (e.g., z-direction dimension) of the recess 432. The greater vertical dimension D1′ may be due to a top surface of the top electrode layer 138 of each of the memory devices 132a and 132b failing to reach a top surface of the ILD layer 114b and/or a bottom surface of the ESL 116b. As a result, the recesses 428 may be formed through a top portion of the ILD layer 114b before etching portions of the second spacer layer 150 to expose the top electrode layer 138 of each of the memory devices 132a and 132b. In some implementations, the vertical dimension D1′ of the recesses 428 may be approximately 100 angstroms to approximately 300 angstroms greater than the vertical dimension D2′ of the recess 432. Alternatively, the vertical dimension D1′ of each of the recesses 428 may be equal to the vertical dimension D2′ of the recess 432. In the case where the vertical dimensions D1′ and D2′ are equal, the top surfaces of the top electrode layer 138 of each of the memory devices 132a and 132b may be co-planar with or approximately co-planar with top surfaces of the metallization structure 122d. The vertical dimension D1′ of the recesses 428 may be equal to or approximately equal to the vertical dimension D1 of the interconnect structures 124b and 124c that are formed in the recesses 428. The vertical dimension D2′ of the recess 432 may be equal to or approximately equal to the vertical dimension D2 of the interconnect structure 124d that is formed in the recess 432.

The second spacer layer 150 may include a material having a low etch selectivity with respect to the ILD layer 114b, so that when the ILD layer 114b is etched to form the recesses 428 over the top electrode layers 138, the second spacer layer 150 may also be etched to expose top surfaces of the top electrode layers 138. For example, a ratio of the etch rates of the ILD layer 114b, and of the second spacer layer 150 may be approximately 1:1 so that the ILD layer 114 b and the second spacer layer 150 can be etched using the same etchant to form recesses 428 exposing top surfaces of the top electrode layers 138. In some implementations, the second spacer layer 150 and the ILD layer 114b may include materials that have the same or similar etch rates for a particular etchant that may be used to form the recesses 428 over the top electrode layers 138. In some implementations, the second spacer layer 150 and the ILD layer 114b may include the same or similar materials.

A thickness t2 of the second spacer layer 150, which may be smaller than thicknesses t1, t3, and t4 of the first spacer layers 148, the third spacer layers 152, and the fourth spacer layers 154, respectively, facilitates complete etching of the second spacer layer 150 when forming the recesses 428 over the top electrode layers 138. The smaller thickness t2 in comparison to the thicknesses t1, t3, and t4 of the remaining spacer layers ensures that the entire portion of the second spacer layer 150 to be etched to expose the top surfaces of the top electrode layers 138 can be removed in an etch operation.

As shown in FIG. 4M, one or more deposition tools may be used to deposit conductive material 436 in the recesses 428, 430, 432, and 434 to form the metallization structure 122e and 122f and the interconnect structures 124b and 124c in the memory region 126, and to form the metallization structure 122g and the interconnect structure 124d in the logic region 128. The conductive material may be deposited using a PVD technique, an ALD technique, a CVD technique, an electroplating technique (e.g., an electro-chemical plating technique), and/or another suitable deposition technique. As noted herein, the conductive material 436 to form the metallization structures 122e-122g and the interconnect structures 124b-124d may include, for example, tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included in the metallization structures 122e-122g and the interconnect structures 124b-124d. The one or more liner layers may include barrier liners, adhesion liners, and/or another type of liners. Examples of materials for the one or more liners include tantalum nitride (TaN) and/or titanium nitride (TiN), among other examples.

As shown in FIG. 4N, a planarization tool may be used to planarize the surface of the ILD layer 114c to remove the dielectric masking layer 424 and excess portions of the conductive material 436 formed on the dielectric masking layer 424 and/or over the top surfaces of the ILD layer 114c.

The metallization structures 122e and 122f are connected to the top electrode layer 138 of each memory device 132a and 132b through the interconnect structures 124b and 124c, respectively. The interconnect structures 124b and 124c are in direct contact with a surface of the top electrode layer 138 of memory devices 132a and 132b, respectively. In some implementations, the surface of the top electrode layer 138 of each memory device 132a and 132b with which the interconnect structures 124b and 124c are in direct contact is curved. Top surfaces of the metallization structures 122e-122g may be co-planar with or approximately co-planar with each other.

The metallization structure 122g is connected to the metallization structure 122d through the interconnect structure 124d. The interconnect structure 124d is in direct contact with a surface of the metallization structure 122d.

As indicated above, FIGS. 4A-4N are provided as an example. Other examples may differ from what is described with regard to FIGS. 4A-4N.

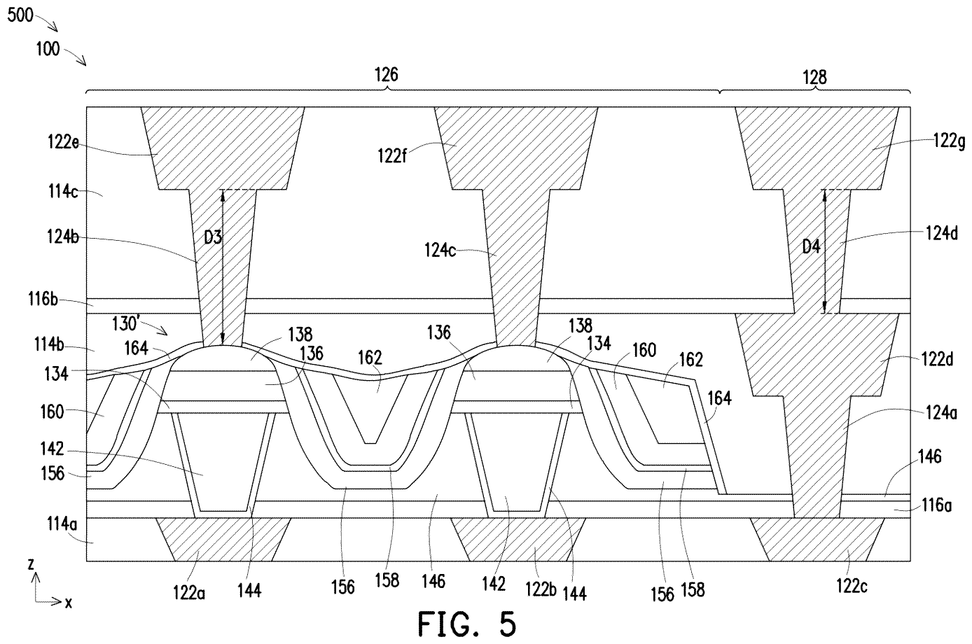

FIG. 5 is a diagram of an example implementation 500 of a portion of the semiconductor device 100 including the semiconductor structure 130′. As shown in FIG. 5, the example implementation 500 of a portion of the semiconductor device 100 including the semiconductor structure 130′ may include a similar arrangement of layers and/or structures as the example implementation 300 of a portion of the semiconductor device 100 including the semiconductor structure 130 illustrated and described in connection with FIG. 3. For example, the semiconductor device 100 in the example implementation 500 is divided into a memory region 126 and a logic region 128, and includes ILD layers 114a, 114b, and 114c, ESLs 116a and 116b, metallization structures 122a, 122b, and 122c in ILD layer 114a, metallization structure 122d in ILD layer 114b, and metallization structures 122e, 122f, and 122g in ILD layer 114c. In addition, as noted in connection with FIG. 1D, the components 134-146 in the semiconductor structure 130′ are the same as the components 134-146 in the semiconductor structure 130. However, the arrangement of spacer layers 156, 158, 160, 162, and 164 in the semiconductor structure 130′ differs from that of spacer layers 148, 150, 152, and 154 in the semiconductor structure 130. For example, the interconnect structure 124b is disposed between and connects a top electrode layer 138 of a memory device 132a′ and metallization structure 122e, and the interconnect structure 124c is disposed between and connects a top electrode layer 138 of a memory device 132b′ and metallization structure 122f. The interconnect structures 124b and 124c are disposed through part of ILD layer 114c, through ESL 116b, through part of ILD layer 114b, and through portions of the fifth spacer layer 164 on top surfaces of the top electrode layers 138. The interconnect structures 124b and 124c respectively land on a top surface of the top electrode layer 138 of the memory device 132a′ and the memory device 132b′.

In some implementations, a vertical dimension D3 (e.g., z-direction dimension) (e.g., height or depth) of each interconnect structure 124b and 124c may be greater than a vertical dimension D4 (e.g., z-direction dimension) of the interconnect structure 124d. The greater vertical dimension D3 may be due to a top surface of the top electrode layer 138 of each of the memory devices 132a′ and 132b′ failing to reach a top surface of the ILD layer 114b and/or a bottom surface of the ESL 116b. As a result, the interconnect structures 124b and 124c may be formed through a top portion of the ILD layer 114b to land on the top electrode layer 138 of each of the memory devices 132a′ and 132b′. In some implementations, the vertical dimension D3 of the interconnect structures 124a and 124b may be approximately 100 angstroms to approximately 300 angstroms greater than the vertical dimension D4 of the interconnect structure 124d. Alternatively, the vertical dimension D3 of each of the interconnect structures 124b and 124c may be equal to the vertical dimension D4 of the interconnect structure 124d. In the case where the vertical dimensions D3 and D4 are equal, the top surfaces of the top electrode layer 138 of each of the memory devices 132a′ and 132b′ may be co-planar with or approximately co-planar with the top surface of the metallization structure 122d. If the top surfaces of the top electrode layer 138 of each of the memory devices 132a′ and 132b′ are co-planar with or approximately co-planar with the top surface of the metallization structure 122d, the vertical (e.g., z-direction) dimension of the bottom interconnect structures 140 may be larger than if the top surface of the top electrode layer 138 of each of the memory devices 132a′ and 132b′ fails to reach a top surface of the ILD layer 114b and/or a bottom surface of the ESL 116b. In some implementations, the vertical dimensions D3 and D4 in the example implementation 500 may be equal to or approximately equal to the vertical dimensions D1 and D2 in the example implementation 300.

The metallization structures 122e and 122f are respectively connected to the top electrode layer 138 of each memory device 132a′ and 132b′ through the interconnect structures 124b and 124c. The interconnect structures 124b and 124c are in direct contact with a surface of the top electrode layer 138 of memory devices 132a′ and 132b′, respectively.

As indicated above, FIG. 5 is provided as an example. Other examples may differ from what is described with regard to FIG. 5.

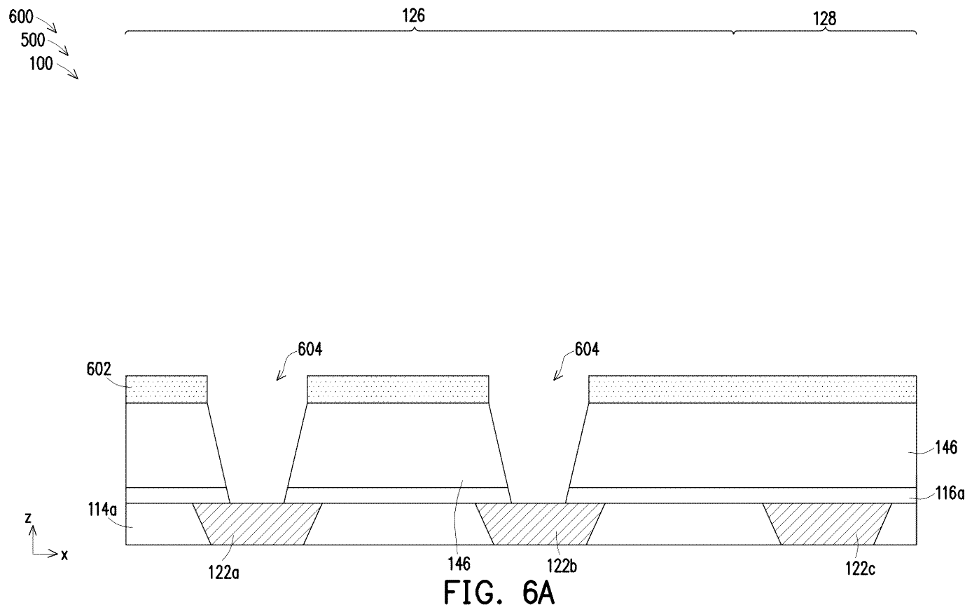

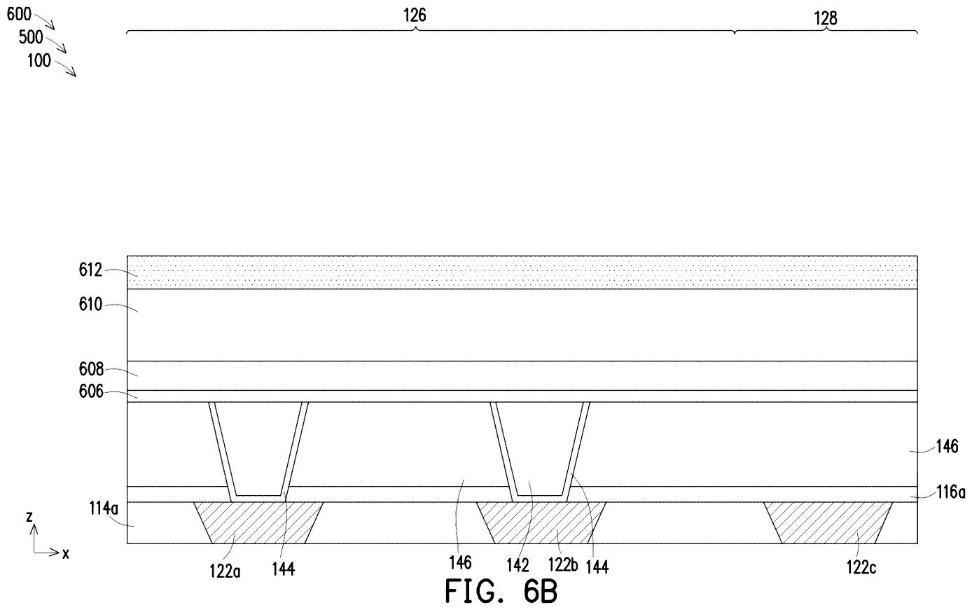

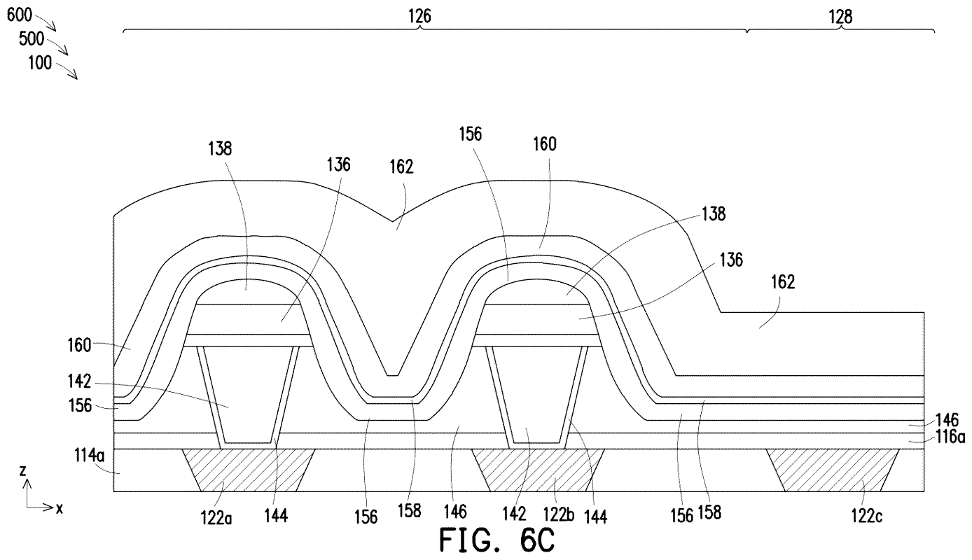

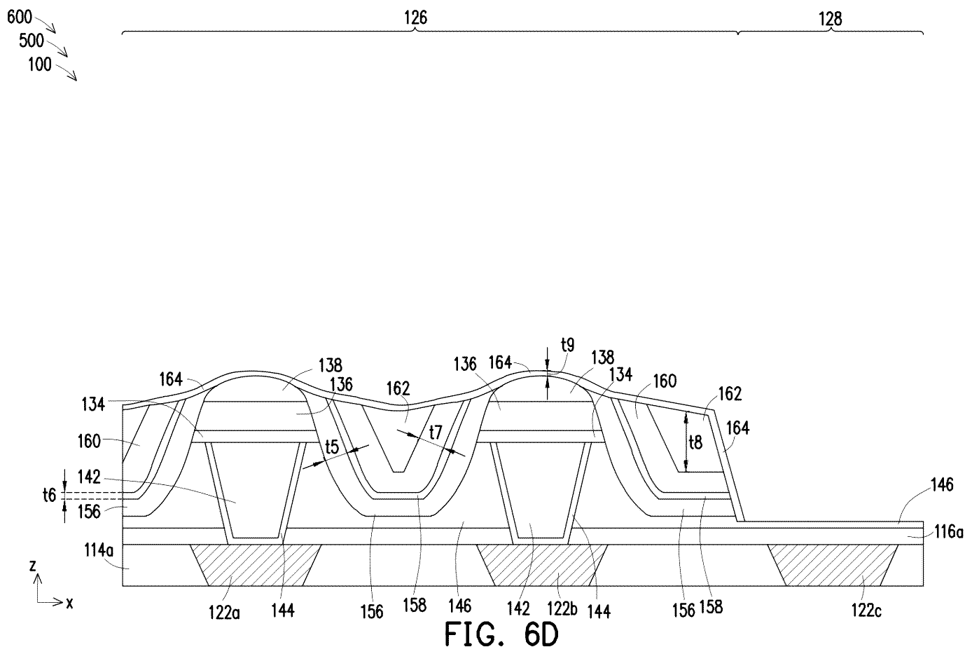

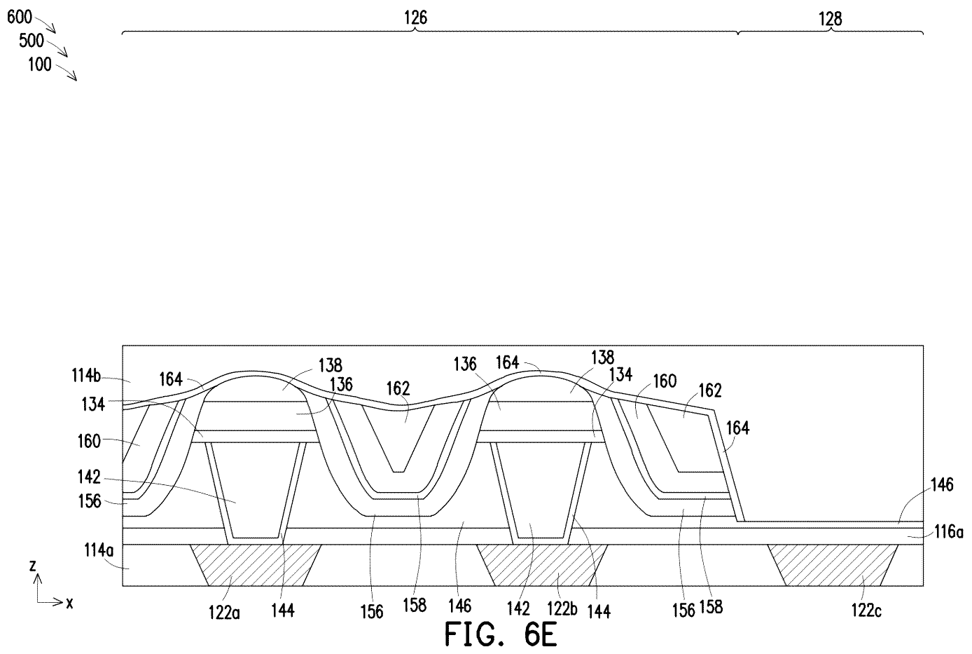

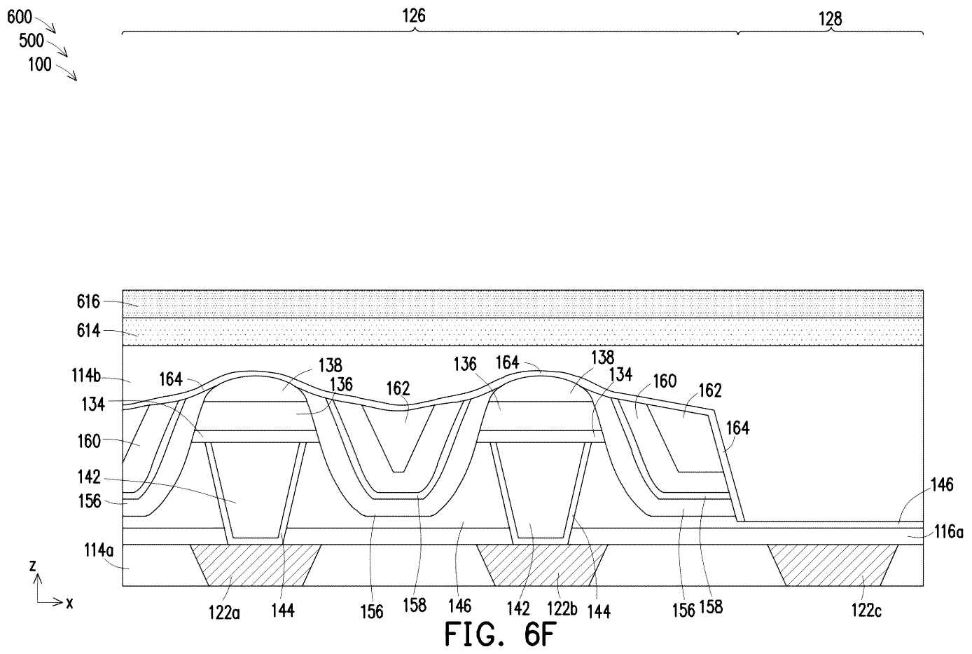

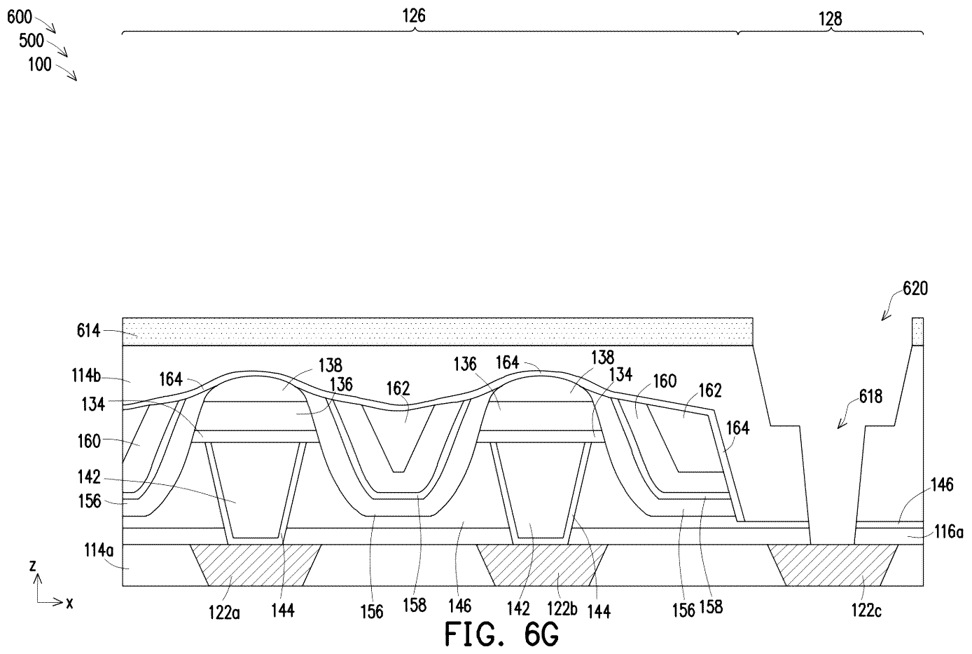

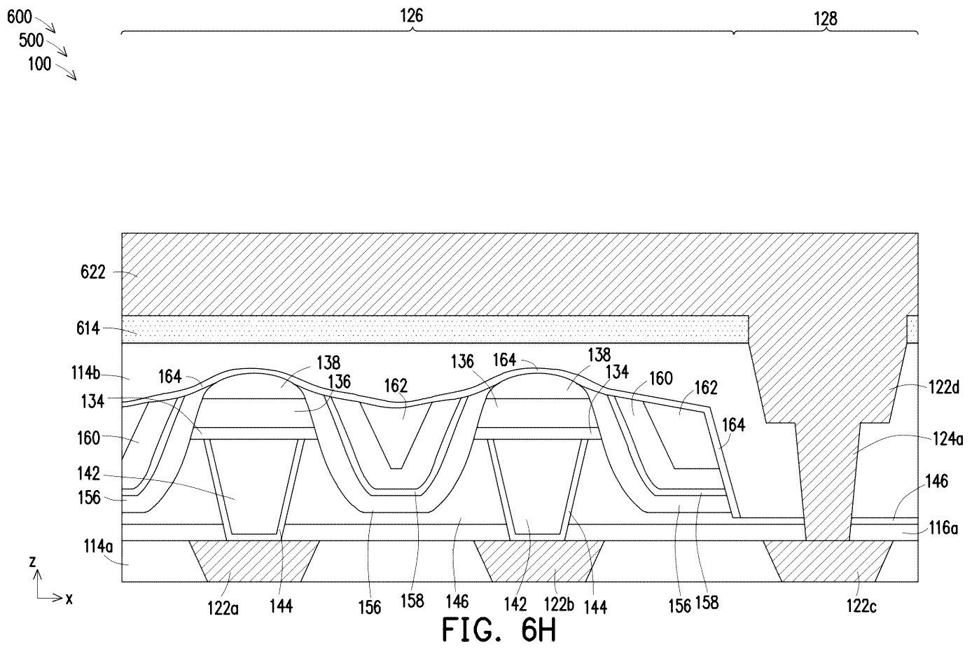

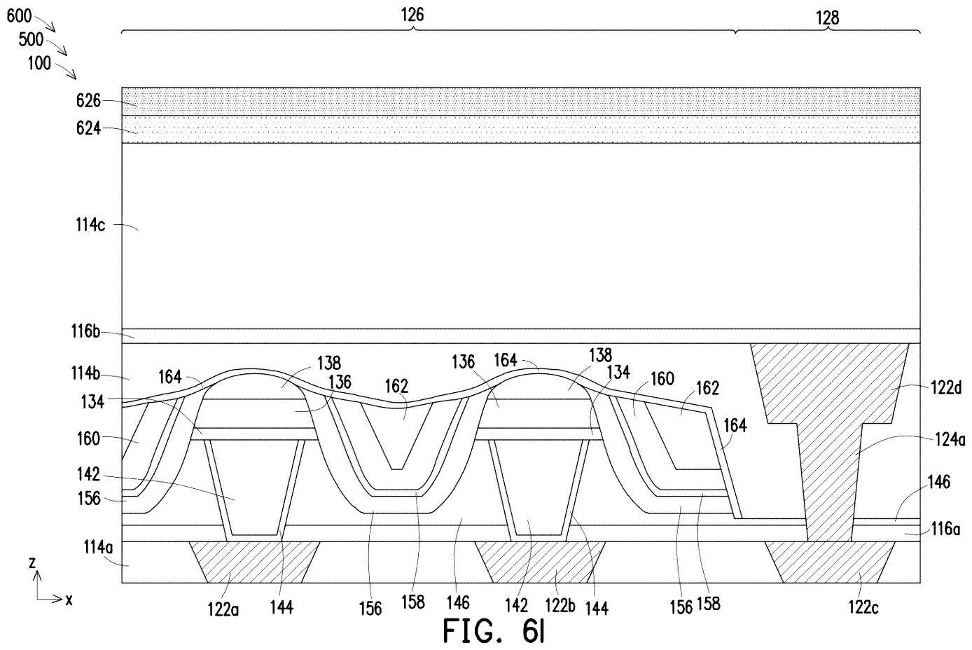

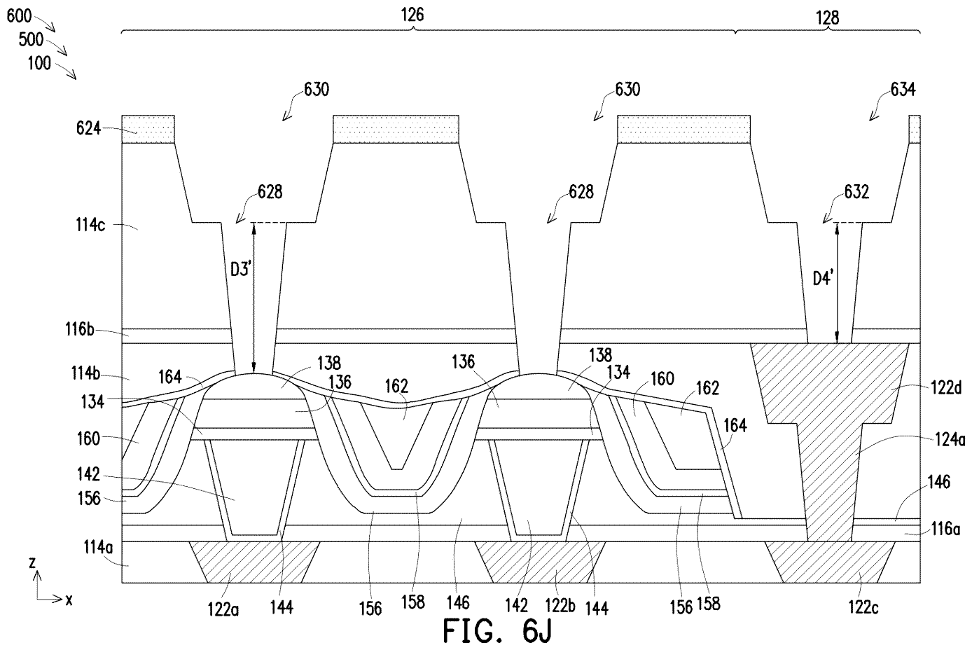

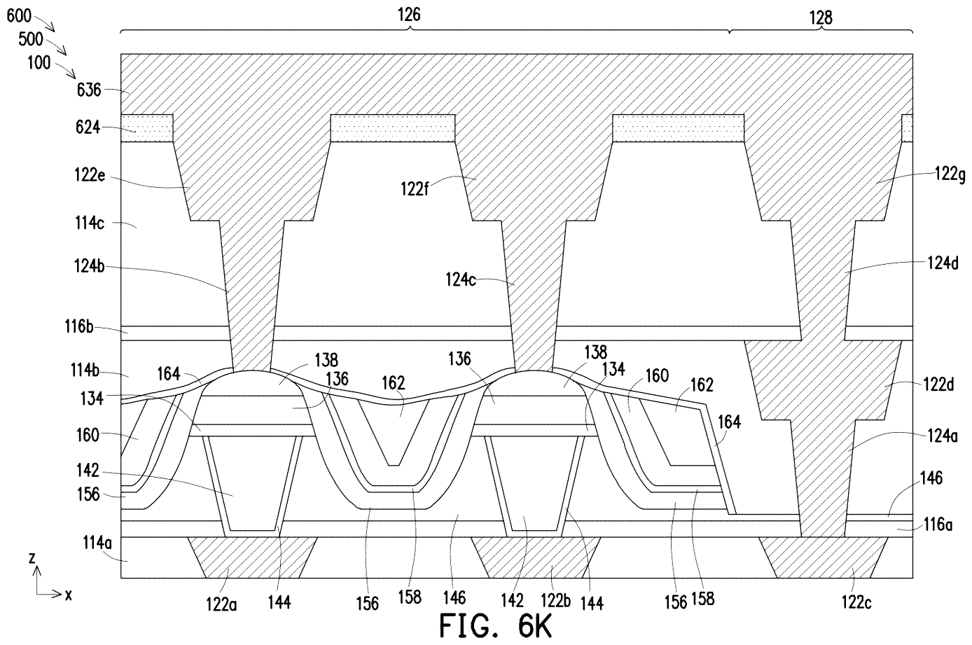

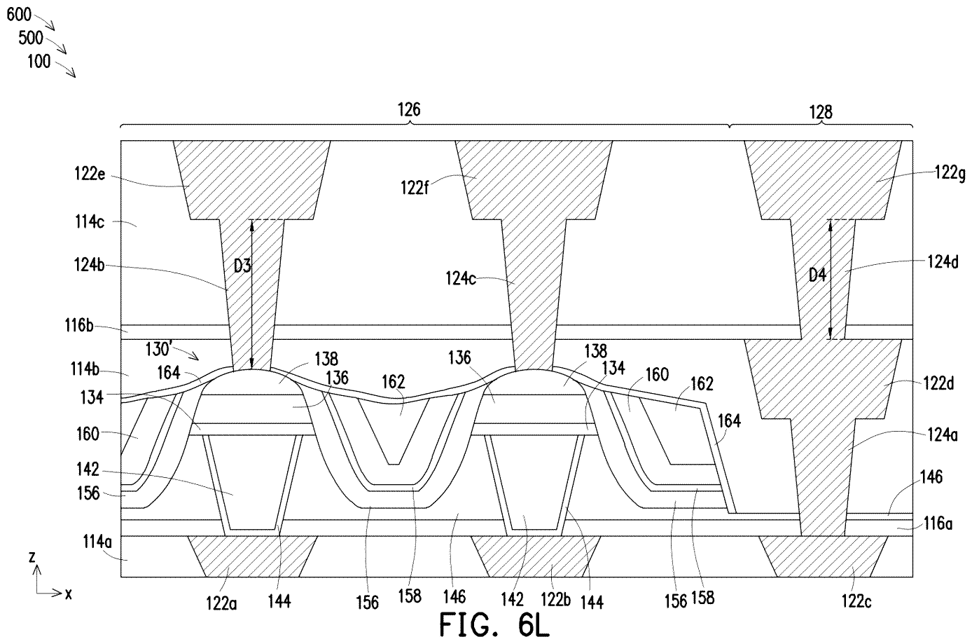

FIGS. 6A-6L are diagrams of an example implementation 600 of forming a portion of a semiconductor device 100 including the semiconductor structure 130′ described herein. In some implementations, one or more of the semiconductor processing operations described in connection with FIGS. 6A-6L may be performed using one or more semiconductor processing tools, such as a deposition tool, an exposure tool, a developer tool, an etch tool, a planarization tool, a wafer/die transport tool, and/or another type of semiconductor processing tool. In some implementations, one or more of the semiconductor processing operations described in connection with FIGS. 6A-6L may be performed as part of the process for forming the semiconductor device 100 described in connection with FIGS. 2A-2E.

The example implementation 600 of forming a portion of a semiconductor device 100 including the semiconductor structure 130′ may include similar processing steps and a similar arrangement of layers and/or structures to the example implementation 400 of forming a portion of a semiconductor device 100 including the semiconductor structure 130 illustrated and described in connection with FIGS. 4A-4N. For example, the processing steps illustrated in FIGS. 6A and 6B, and the components 602-612, are the same as the processing steps illustrated in FIGS. 4A and 4B, and the components 402-412.

As shown in FIG. 6C, portions of the blanket MTJ structure 608 and the blanket bottom electrode layer 606 are removed in one or more etching processes, where the plurality of mask structure portions, each including a portion of the top electrode mask layer 610 and a portion of the dielectric mask layer 612 on the portion of the top electrode mask layer 610, are used as masks that cover portions of the blanket MTJ structure 608 and underlying portions of the blanket bottom electrode layer 606. Exposed portions of the blanket MTJ structure 608 and of the blanket bottom electrode layer 606 that are not covered by the plurality of mask structure portions are removed in the one or more etching processes to pattern the blanket MTJ structure 608 into the MTJ structures 136 and to pattern the blanket bottom electrode layer 606 into the bottom electrode layers 134. In addition, the one or more etching processes result in removal of the portions of the dielectric mask layers 612, and patterning of the remaining portions of the top electrode mask layers 610 into the top electrode layers 138, where each top electrode layer 138 may have a curved top surface. In some implementations, an etch tool uses a wet etch technique, a dry etch technique, a plasma-enhanced etch technique, and/or another type of etch technique to perform the one or more etching processes.

The resulting patterned MTJ structures 136 and patterned bottom electrode layers 134 each include angled side surfaces, such that the MTJ structures 136 and bottom electrode layers 134 each taper to a larger width (e.g., x-direction dimension) in the downward z-direction. The one or more etching processes cause removal of portions of the dielectric layer 146 between and/or adjacent to the memory devices 132a and 132b to result in a curved profile of the top surfaces of the portions of the dielectric layer 146 between and/or adjacent to the memory devices 132a′ and 132b′.

As further shown in FIG. 6C, a stacked arrangement of the first spacer layer 156, the second spacer layer 158, the third spacer layer 160, and the fourth spacer layer 162 is conformally deposited on exposed side surfaces of the bottom electrode layers 134, on exposed side surfaces of the MTJ structures 136, on exposed side and top surfaces of the top electrode layers 138, and on the exposed surfaces of the dielectric layer 146 between and/or adjacent to the memory devices 132a′ and 132b′. In more detail, the first spacer layer 156 is conformally deposited on exposed side surfaces of the bottom electrode layers 134, on exposed side surfaces of the MTJ structures 136, on exposed side and top surfaces of the top electrode layers 138, and on the exposed surfaces of the dielectric layer 146 between and/or adjacent to the memory devices 132a′ and 132b′. The first spacer layer 156 is deposited on the exposed surfaces of the dielectric layer 146 in the memory region 126 and in the logic region 128. A deposition tool may be used to deposit the first spacer layer 148 using an ALD technique, a CVD technique, and/or another suitable deposition technique.

The second spacer layer 158 is conformally deposited on exposed surfaces of the first spacer layer 156. A deposition tool may be used to deposit the second spacer layer 158 using an ALD technique, a CVD technique, and/or another suitable deposition technique. The third spacer layer 160 is conformally deposited on exposed surfaces of the second spacer layer 158. A deposition tool may be used to deposit the third spacer layer 160 using an ALD technique, a CVD technique, and/or another suitable deposition technique. The fourth spacer layer 162 is conformally deposited on exposed surfaces of the third spacer layer 160. A deposition tool may be used to deposit the fourth spacer layer 162 using an ALD technique, a CVD technique, and/or another suitable deposition technique.

As shown in FIG. 6D, an etch tool performs one or more etch operations to remove portions of the first spacer layer 156, the second spacer layer 158, the third spacer layer 160, and the fourth spacer layer 162 from the top surfaces of top electrode layers 138. Portions of the first spacer layer 156, the second spacer layer 158, the third spacer layer 160, and the fourth spacer layer 162 are further removed from areas between and/or laterally adjacent to top electrode layers 138 to reduce heights (e.g., z-direction dimensions) of the first-fourth spacer layers 156-162 so that the topmost surfaces of the first-fourth spacer layers 156-162 are under topmost surfaces of the top electrode layers 138. Portions of the first-fourth spacer layers 156-162 are further removed from one or more surfaces of the dielectric layer 146 (e.g., surfaces extending in the horizontal direction (x-direction)) on the side of the semiconductor structure 130′ (e.g., at an end of the memory region 126 and in the logic region 128). In some implementations, the etch operation includes a dry etch operation (e.g., a plasma-based etch operation, a gas-based etch operation), a wet chemical etch operation, and/or another type of etch operation.

As further shown in FIG. 6D, the fifth spacer layer 164 (e.g., capping spacer layer) is conformally deposited on remaining portions of the stacked arrangement of the first spacer layer 156, the second spacer layer 158, the third spacer layer 160, and the fourth spacer layer 162, and on the top surface of the top electrode layer 138 of each memory device 132a′ and 132b′. A deposition tool may be used to deposit the fifth spacer layer 164 using an ALD technique, a CVD technique, and/or another suitable deposition technique. A thickness t9 of the fifth spacer layer 164 may be smaller than thicknesses t5, t7, and t8 of the remaining portions of the first spacer layer 156, the third spacer layer 160, and the fourth spacer layer 162, respectively. In some implementations, a thickness t6 of the remaining portions of the second spacer layer 158 is approximately equal to the thickness t9 of the fifth spacer layer 164. The remaining portions of the first-fourth spacer layers 156-162 may be referred to herein as first spacer layers 156, second spacer layers 158, third spacer layers 160, and/or fourth spacer layers 162.

The processing steps illustrated in FIGS. 6E-6L, and the components 614-636, are the same as the processing steps illustrated in FIGS. 4G-4N, and the components 414-436, with the exception that, instead of extending through the second spacer layer 150, the interconnect structures 124b and 124c extend through portions of the fifth spacer layer 164 on the top surfaces of the top electrode layers 138 to land on and contact the top surfaces of the top electrode layers 138. In more detail, as shown in FIG. 6J, one or more etch operations may be performed to etch through the ILD layer 114c, the ESL 116b, the ILD layer 114b, and the fifth spacer layer 164 to form recesses 628 and 630 in the memory region 126, and to etch through the ILD layer 114c and the ESL 116b to form recesses 632 and 634 in the logic region 128. Bottom surfaces of the recesses 628 expose portions of top surfaces of the underlying top electrode layers 138 of the memory devices 132a′ and 132b′, and a bottom surface of the recess 632 exposes a portion of the top surface of the underlying metallization structure 122d. In some implementations, the recesses 628 and 632 are simultaneously formed during the same etch operation, and the recesses 630 and 634 are simultaneously formed during the same etch operation. The same mask structure (e.g., dielectric masking layer 624 and photoresist layer 626) is used to form the recesses 628, 630, 632, and 634.

In some implementations, a dual damascene process is used to form the recesses 628, 630, 632, and 634. For example, the recesses 628 may be formed in and/or through a bottom portion of the ILD layer 114c, through the ESL 116b, through a top portion of the ILD layer 114b, and through the fifth spacer layer 164. The recess 632 may be formed in and/or through a bottom portion of the ILD layer 114c and through the ESL 116b. The recesses 630 and 632 may be formed in the top portion of the ILD layer 114c above the recesses 628 and 632, respectively.

In some implementations, a vertical dimension D3′ (e.g., z-direction dimension) (e.g., height or depth) of each recess 628 may be greater than a vertical dimension D4′ (e.g., z-direction dimension) of the recess 632. The greater vertical dimension D3′ may be due to a top surface of the top electrode layer 138 of each of the memory devices 132a′ and 132b′ failing to reach a top surface of the ILD layer 114b and/or a bottom surface of the ESL 116b. As a result, the recesses 628 may be formed through a top portion of the ILD layer 114b before etching portions of the fifth spacer layer 164 to expose the top electrode layer 138 of each of the memory devices 132a′ and 132b′. In some implementations, the vertical dimension D3′ of the recesses 628 may be approximately 100 angstroms to approximately 300 angstroms greater than the vertical dimension D4′ of the recess 632. Alternatively, the vertical dimension D3′ of each of the recesses 628 may be equal to the vertical dimension D4′ of the recess 632. In the case where the vertical dimensions D3′ and D4′ are equal, the top surfaces of the top electrode layer 138 of each of the memory devices 132a′ and 132b′ may be co-planar with or approximately co-planar with top surfaces of the metallization structure 122d. The vertical dimension D3′ of the recesses 628 may be equal to or approximately equal to the vertical dimension D3 of the interconnect structures 124b and 124c that are formed in the recesses 628. The vertical dimension D4′ of the recess 632 may be equal to or approximately equal to the vertical dimension D4 of the interconnect structure 124d that is formed in the recess 632.

The fifth spacer layer 164 may include a material having a low etch selectivity with respect to the ILD layer 114b, so that when the ILD layer 114b is etched to form the recesses 628 over the top electrode layers 138, the fifth spacer layer 164 may also be etched to expose top surfaces of the top electrode layers 138. For example, a ratio of the etch rates of the ILD layer 114 b, and of the fifth spacer layer 164 may be approximately 1:1 so that the ILD layer 114 b and the fifth spacer layer 164 can be etched using the same etchant to form recesses 628 exposing top surfaces of the top electrode layers 138. In some implementations, the fifth spacer layer 164 and the ILD layer 114b may include materials that have the same or similar etch rates for a particular etchant that may be used to form the recesses 628 over the top electrode layers 138. In some implementations, the fifth spacer layer 164 and the ILD layer 114b may include the same or similar materials.

A thickness t9 of the fifth spacer layer 164, which may be smaller than thicknesses t5, t7, and t8 of the first spacer layers 156, the third spacer layers 160, and the fourth spacer layers 162, respectively, facilitates complete etching of the fifth spacer layer 164 when forming the recesses 628 over the top electrode layers 138. The smaller thickness t9 in comparison to the thicknesses t5, t7, and t8 of the first, third and fourth spacer layers 156, 160, and 162 ensures that the entire portion of the fifth spacer layer 164 to be etched to expose the top surfaces of the top electrode layers 138 can be removed in an etch operation.

The metallization structures 122e and 122f are connected to the top electrode layer 138 of each memory device 132a′ and 132b′ through the interconnect structures 124b and 124c, respectively. The interconnect structures 124b and 124c are in direct contact with a surface of the top electrode layer 138 of memory devices 132a′ and 132b′, respectively. In some implementations, the surface of the top electrode layer 138 of each memory device 132a′ and 132b′ with which the interconnect structures 124b and 124c are in direct contact is curved. Top surfaces of the metallization structures 122e-122g may be co-planar with or approximately co-planar with each other.

As indicated above, FIGS. 6A-6L are provided as an example. Other examples may differ from what is described with regard to FIGS. 6A-6L.

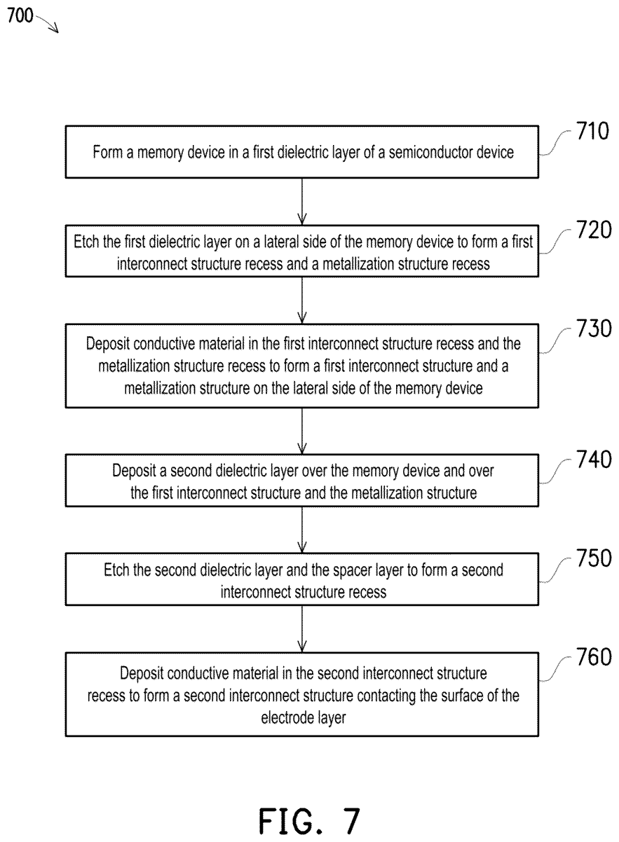

FIG. 7 is a flowchart of an example process 700 associated with a method of forming a semiconductor device. In some implementations, one or more process blocks of FIG. 7 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 7, process 700 may include forming a memory device in a first dielectric layer of a semiconductor device (block 710). For example, one or more semiconductor processing tools may be used to form a memory device (e.g., memory device 132a, 132b, 132a′, 132b′) in a first dielectric layer (e.g., ILD layer 114b) of a semiconductor device (e.g., semiconductor device 100), as described herein. In some implementations, the memory device includes a magnetic tunnel junction (MTJ) structure (e.g., MTJ structure 136), an electrode layer (e.g., top electrode layer 138) on the MTJ structure, and a spacer layer (e.g., second spacer layer 150, fifth spacer layer 164) on the electrode layer.

As further shown in FIG. 7, process 700 may include etching the first dielectric layer on a lateral side of the memory device to form a first interconnect structure recess and a metallization structure recess (block 720). For example, one or more semiconductor processing tools may be used to etch the first dielectric layer on a lateral side of the memory device to form a first interconnect structure recess (e.g., recess 418, 618) and a metallization structure recess (e.g., recess 420, 620), as described herein.

As further shown in FIG. 7, process 700 may include depositing conductive material in the first interconnect structure recess and the metallization structure recess to form a first interconnect structure and a metallization structure on the lateral side of the memory device (block 730). For example, one or more semiconductor processing tools may be used to deposit conductive material (e.g., conductive material 422, 622) in the first interconnect structure recess and the metallization structure recess to form a first interconnect structure (e.g., interconnect structure 124a) and a metallization structure (e.g., metallization structure 122d) on the lateral side of the memory device, as described herein.

As further shown in FIG. 7, process 700 may include depositing a second dielectric layer over the memory device and over the first interconnect structure and the metallization structure (block 740). For example, one or more semiconductor processing tools may be used to deposit a second dielectric layer (e.g., ILD layer 114c) over the memory device and over the first interconnect structure and the metallization structure, as described herein.

As further shown in FIG. 7, process 700 may include etching the second dielectric layer and the spacer layer to form a second interconnect structure recess (block 750). For example, one or more semiconductor processing tools may be used to etch the second dielectric layer and the spacer layer to form a second interconnect structure recess (e.g., recess 428, 628), as described herein. In some implementations, the second interconnect structure recess exposes a surface of the electrode layer of the memory device.

As further shown in FIG. 7, process 700 may include depositing conductive material in the second interconnect structure recess to form a second interconnect structure contacting the surface of the electrode layer (block 760). For example, one or more semiconductor processing tools may be used to deposit conductive material (e.g., conductive material 436, 636) in the second interconnect structure recess to form a second interconnect structure (e.g., interconnect structure 124b, 124c) contacting the surface of the electrode layer, as described herein. In some implementations, the first interconnect structure is in a first interconnect level (e.g., via level V4). In some implementations, the second interconnect structure is in a second interconnect level (e.g., via-5 (V5) layer) over the first interconnect level.

Process 700 may include additional implementations, such as any single implementation or any combination of implementations described below and/or in connection with one or more other processes described elsewhere herein.

In a first implementation, process 700 includes etching the second dielectric layer to form a third interconnect structure recess (e.g., recess 432, 632) on a lateral side of the second interconnect structure recess, where the third interconnect structure recess exposes a surface of the metallization structure, and depositing the conductive material in the third interconnect structure recess to form a third interconnect structure (e.g., interconnect structure 124d) contacting the surface of the metallization structure, where the third interconnect structure is in the second interconnect level.

In a second implementation, alone or in combination with the first implementation, the memory device and the second interconnect structure are in a first region (e.g., memory region 126) of the semiconductor device, and the third interconnect structure, the metallization structure, and the first interconnect structure are in a second region (e.g., logic region 128) of the semiconductor device.

In a third implementation, alone or in combination with one or more of the first and second implementations, a vertical dimension (e.g., vertical dimension D1′, D3′) of the second interconnect structure recess is larger than a vertical dimension (e.g., vertical dimension D2′, D4′) of the third interconnect structure recess.

In a fourth implementation, alone or in combination with one or more of the first through third implementations, process 700 includes etching a first portion of the second dielectric layer over the second interconnect structure recess to form a first additional metallization structure recess (e.g., recess 430, 630), etching a second portion of the second dielectric layer over the third interconnect structure recess to form a second additional metallization structure recess (e.g., recess 434, 634), depositing the conductive material in the first additional metallization structure recess to form a first additional metallization structure (e.g., metallization structure 122e, 122f) contacting the second interconnect structure, and depositing the conductive material in the second additional metallization structure recess to form a second additional metallization structure (e.g., metallization structure 122g) contacting the third interconnect structure, where etching the first portion and etching the second portion are performed with a same mask (e.g., dielectric masking layer 424, 624).

In a fifth implementation, alone or in combination with one or more of the first through fourth implementations, the metallization structure is in a first metallization level (e.g., metal-5 (M5) layer), and the first additional metallization structure and the second additional metallization structure are in a second metallization level (e.g., metal-6 (M6) layer) over the first metallization level and over the second interconnect level.

In a sixth implementation, alone or in combination with one or more of the first through fifth implementations, process 700 includes etching a portion of the first dielectric layer over the spacer layer to form the second interconnect structure recess.

In a seventh implementation, alone or in combination with one or more of the first through sixth implementations, a portion of the spacer layer is formed on sides of the memory device, and one or more additional spacer layers (e.g. third spacer layer 152, e.g., fourth spacer layer 154) are formed on the portion of the spacer layer.

In an eighth implementation, alone or in combination with one or more of the first through seventh implementations, one or more additional spacer layers (e.g., first spacer layer 156, second spacer layer 158, third spacer layer 160, fourth spacer layer 162) are formed under a portion of the spacer layer.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

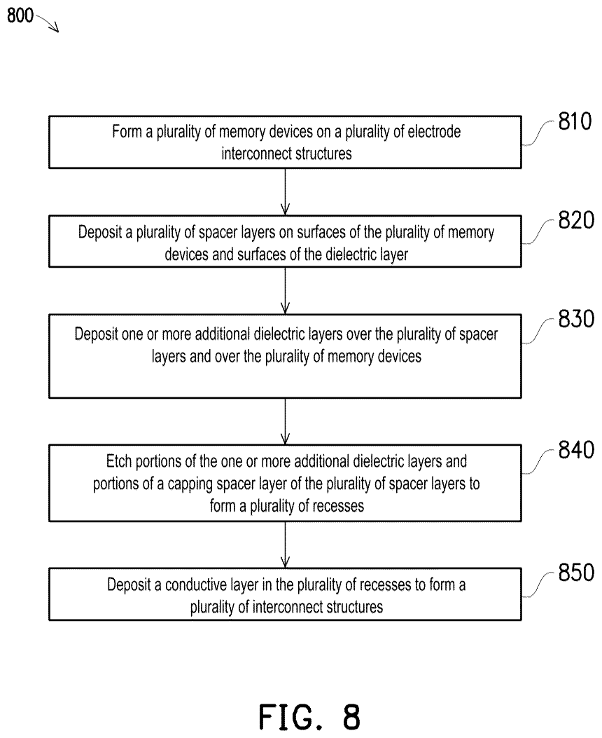

FIG. 8 is a flowchart of an example process 800 associated with a method of forming a semiconductor device. In some implementations, one or more process blocks of FIG. 8 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 8, process 800 may include forming a plurality of memory devices on a plurality of electrode interconnect structures (block 810). For example, one or more semiconductor processing tools may be used to form a plurality of memory devices (e.g., memory devices 132a, 132b, 132a′, 132b′) on a plurality of electrode interconnect structures (e.g., bottom interconnect structures 140), as described herein. In some implementations, the plurality of electrode interconnect structures are formed in a dielectric layer (e.g., dielectric layer 146). In some implementations, each memory device of the plurality of memory devices includes a first electrode layer (e.g., bottom electrode layer 134) on an electrode interconnect structure of the plurality of electrode interconnect structures, one or more memory device layers (e.g., MTJ structure 136) on the first electrode layer, and a second electrode layer (e.g., top electrode layer 138) on the one or more memory device layers.

As further shown in FIG. 8, process 800 may include depositing a plurality of spacer layers on surfaces of the plurality of memory devices and surfaces of the dielectric layer (block 820). For example, one or more semiconductor processing tools may be used to deposit a plurality of spacer layers (e.g., first-fourth spacer layers 148-154, first-fifth spacer layers 156-164) on surfaces of the plurality of memory devices and surfaces of the dielectric layer, as described herein.

As further shown in FIG. 8, process 800 may include depositing one or more additional dielectric layers over the plurality of spacer layers and over the plurality of memory devices (block 830). For example, one or more semiconductor processing tools may be used to deposit one or more additional dielectric layers (e.g., ILD layer 114b, ESL 116b, ILD layer 114c) over the plurality of spacer layers and over the plurality of memory devices, as described herein.

As further shown in FIG. 8, process 800 may include etching portions of the one or more additional dielectric layers and portions of a capping spacer layer of the plurality of spacer layers to form a plurality of recesses (block 840). For example, one or more semiconductor processing tools may be used to etch portions of the one or more additional dielectric layers and portions of a capping spacer layer (e.g., second spacer layer 150, e.g., fifth spacer layer 164) of the plurality of spacer layers to form a plurality of recesses (e.g., recesses 428, 628), as described herein. In some implementations, each recess of the plurality of recesses exposes a second electrode layer portion of an underlying memory device of the plurality of memory devices.

As further shown in FIG. 8, process 800 may include depositing a conductive layer in the plurality of recesses to form a plurality of interconnect structures (block 850). For example, one or more semiconductor processing tools may be used to deposit a conductive layer (e.g., conductive material 436, 636) in the plurality of recesses to form a plurality of interconnect structures (e.g., interconnect structures 124b, 124c), as described herein. In some implementations, each interconnect structure of the plurality of interconnect structures contacts the second electrode layer portion of the underlying memory device.

Process 800 may include additional implementations, such as any single implementation or any combination of implementations described below and/or in connection with one or more other processes described elsewhere herein.

In a first implementation, a thickness (e.g., thickness t2, t9) of the capping spacer layer is smaller than thicknesses (e.g., thicknesses t1, t3-t5, t7, t8) of other spacer layers of the plurality of spacer layers.

In a second implementation, alone or in combination with the first implementation, parts of the capping spacer layer are disposed on sides of the plurality of memory devices between two other spacer layers (e.g., first spacer layer 148, third spacer layer 152) of the plurality of spacer layers.

In a third implementation, alone or in combination with one or more of the first and second implementations, depositing the plurality of spacer layers includes depositing a first spacer layer (e.g., first spacer layer 148) on side surfaces and a top surface of the second electrode layer of each memory device, removing portions of the first spacer layer from the top surface of the second electrode layer of each memory device, depositing a stacked spacer layer arrangement on remaining portions of the first spacer layer and on the top surface of the second electrode layer of each memory device, where the stacked spacer layer arrangement includes the capping spacer layer, and one or more additional spacer layers (e.g., third spacer layer 152, fourth spacer layer 154) on the capping spacer layer, and removing portions of the one or more additional spacer layers from the top surface of the second electrode layer of each memory device to expose underlying portions of the capping spacer layer.

In a fourth implementation, alone or in combination with one or more of the first through third implementations, depositing the plurality of spacer layers includes depositing a stacked spacer layer arrangement on side surfaces and a top surface of the second electrode layer of each memory device, where the stacked spacer layer arrangement includes a first spacer layer (e.g., first spacer layer 156), and one or more additional spacer layers (e.g., second-fourth spacer layers 156-162) on the first spacer layer, removing portions of the stacked spacer layer arrangement from the top surface of the second electrode layer of each memory device, and depositing the capping spacer layer on remaining portions of the stacked spacer layer arrangement and on the top surface of the second electrode layer of each memory device.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

In this way, memory devices may include side spacer arrangements and may be manufactured using techniques which facilitate and permit removal of side spacer portions from memory device top electrode surfaces when interconnect structure recesses are formed over memory device top electrodes. For example, materials and/or thicknesses of side spacer portions formed on top electrode surfaces may be controlled to prevent etching resistance of the side spacer portions and permit exposure of the top electrode surfaces by interconnect structure recesses. As a result, interconnect structures (e.g., vias) formed in the interconnect structure recesses may contact the top electrode surfaces without intervening residual spacer material between the interconnect structures and the top electrode surfaces, thereby reducing resistance and creating reliable electrical connections between top electrodes and interconnect structures to increase memory device performance and/or reliability.

Additionally, in the example implementations described herein, interconnect and metallization structures in memory and logic regions may be manufactured using the same etching and deposition processes. Accordingly, processing to manufacture the interconnect and metallization structures in a memory region and corresponding interconnect and metallization structures in a logic region requires fewer masks and fewer steps than processing to manufacture other arrangements of metallization and interconnect structures. The simplified device manufacturing may result in fewer design errors, further increasing device performance and reliability.

As described in greater detail above, some implementations described herein provide a method. The method includes forming a memory device in a first dielectric layer of a semiconductor device, where the memory device includes a magnetic tunnel junction (MTJ) structure, an electrode layer on the MTJ structure, and a spacer layer on the electrode layer. The method includes etching the first dielectric layer on a lateral side of the memory device to form a first interconnect structure recess and a metallization structure recess. The method includes depositing conductive material in the first interconnect structure recess and the metallization structure recess to form a first interconnect structure and a metallization structure on the lateral side of the memory device. The method includes depositing a second dielectric layer over the memory device and over the first interconnect structure and the metallization structure. The method includes etching the second dielectric layer and the spacer layer to form a second interconnect structure recess, where the second interconnect structure recess exposes a surface of the electrode layer of the memory device. The method includes depositing conductive material in the second interconnect structure recess to form a second interconnect structure contacting the surface of the electrode layer, where the first interconnect structure is in a first interconnect level, and where the second interconnect structure is in a second interconnect level over the first interconnect level.

As described in greater detail above, some implementations described herein provide a method. The method includes forming a plurality of memory devices on a plurality of electrode interconnect structures, where the plurality of electrode interconnect structures are formed in a dielectric layer, and where each memory device of the plurality of memory devices includes a first electrode layer on an electrode interconnect structure of the plurality of electrode interconnect structures, one or more memory device layers on the first electrode layer, and a second electrode layer on the one or more memory device layers. The method includes depositing a plurality of spacer layers on surfaces of the plurality of memory devices and surfaces of the dielectric layer. The method includes depositing one or more additional dielectric layers over the plurality of spacer layers and over the plurality of memory devices. The method includes etching portions of the one or more additional dielectric layers and portions of a capping spacer layer of the plurality of spacer layers to form a plurality of recesses, where each recess of the plurality of recesses exposes a second electrode layer portion of an underlying memory device of the plurality of memory devices. The method includes depositing a conductive layer in the plurality of recesses to form a plurality of interconnect structures, where each interconnect structure of the plurality of interconnect structures contacts the second electrode layer portion of the underlying memory device.

As described in greater detail above, some implementations described herein provide a semiconductor device. The semiconductor device includes a device layer. The semiconductor device includes an interconnect layer disposed over the device layer, where the interconnect layer includes a plurality of dielectric layers, where the plurality of dielectric layers include a plurality of metal lines disposed in the plurality of dielectric layers, where a first metal line in a first dielectric layer of the plurality of dielectric layers is spaced apart from a second metal line in a second dielectric layer the plurality of dielectric layers, and where the first metal line is electrically coupled to the second metal line by a first via in the second dielectric layer. The semiconductor device includes a plurality of memory devices arranged side-by-side in the interconnect layer, where each memory device of the plurality of memory devices includes a first electrode layer, a memory device structure on the first electrode layer, and a second electrode layer on the memory device structure. The interconnect layer further includes a plurality of second vias and a plurality of third metal lines disposed in the second dielectric layer, where a second via of the plurality of second vias is disposed between a third metal line of the plurality of third metal lines and the second electrode layer of a memory device of the plurality of memory devices, where the second via contacts a surface of the second electrode layer, where a bottom portion of the second via is disposed through portions of a spacer layer, and where the portions of the spacer layer are disposed on the second electrode layer.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a memory device in a first dielectric layer of a semiconductor device,
wherein the memory device comprises:
a magnetic tunnel junction (MTJ) structure;
an electrode layer on the MTJ structure; and
a spacer layer on the electrode layer;
etching the first dielectric layer on a lateral side of the memory device to form a first interconnect structure recess and a metallization structure recess;
depositing conductive material in the first interconnect structure recess and the metallization structure recess to form a first interconnect structure and a metallization structure on the lateral side of the memory device;
depositing a second dielectric layer over the memory device and over the first interconnect structure and the metallization structure;
etching the second dielectric layer and the spacer layer to form a second interconnect structure recess,
wherein the second interconnect structure recess exposes a surface of the electrode layer of the memory device; and
depositing conductive material in the second interconnect structure recess to form a second interconnect structure contacting the surface of the electrode layer,
wherein the first interconnect structure is in a first interconnect level, and
wherein the second interconnect structure is in a second interconnect level over the first interconnect level.

2. The method of claim 1, further comprising:
etching the second dielectric layer to form a third interconnect structure recess on a lateral side of the second interconnect structure recess,
wherein the third interconnect structure recess exposes a surface of the metallization structure; and
depositing the conductive material in the third interconnect structure recess to form a third interconnect structure contacting the surface of the metallization structure,
wherein the third interconnect structure is in the second interconnect level.

3. The method of claim 2, wherein the memory device and the second interconnect structure are in a first region of the semiconductor device, and
wherein the third interconnect structure, the metallization structure, and the first interconnect structure are in a second region of the semiconductor device.

4. The method of claim 2, wherein a vertical dimension of the second interconnect structure recess is larger than a vertical dimension of the third interconnect structure recess.

5. The method of claim 2, further comprising:
etching a first portion of the second dielectric layer over the second interconnect structure recess to form a first additional metallization structure recess;
etching a second portion of the second dielectric layer over the third interconnect structure recess to form a second additional metallization structure recess;
depositing the conductive material in the first additional metallization structure recess to form a first additional metallization structure contacting the second interconnect structure; and
depositing the conductive material in the second additional metallization structure recess to form a second additional metallization structure contacting the third interconnect structure,
wherein etching the first portion and etching the second portion are performed with a same mask.

6. The method of claim 5, wherein the metallization structure is in a first metallization level, and
wherein the first additional metallization structure and the second additional metallization structure are in a second metallization level over the first metallization level and over the second interconnect level.

7. The method of claim 1, further comprising etching a portion of the first dielectric layer over the spacer layer to form the second interconnect structure recess.

8. The method of claim 1, wherein a portion of the spacer layer is formed on sides of the memory device, and wherein one or more additional spacer layers are formed on the portion of the spacer layer.

9. The method of claim 1, wherein one or more additional spacer layers are formed under a portion of the spacer layer.

10. A method, comprising:
forming a plurality of memory devices on a plurality of electrode interconnect structures,
wherein the plurality of electrode interconnect structures are formed in a dielectric layer, and
wherein each memory device of the plurality of memory devices comprises:
a first electrode layer on an electrode interconnect structure of the plurality of electrode interconnect structures;
one or more memory device layers on the first electrode layer; and
a second electrode layer on the one or more memory device layers;
depositing a plurality of spacer layers on surfaces of the plurality of memory devices and surfaces of the dielectric layer;
depositing one or more additional dielectric layers over the plurality of spacer layers and over the plurality of memory devices;
etching portions of the one or more additional dielectric layers and portions of a capping spacer layer of the plurality of spacer layers to form a plurality of recesses,
wherein each recess of the plurality of recesses exposes a second electrode layer portion of an underlying memory device of the plurality of memory devices; and
depositing a conductive layer in the plurality of recesses to form a plurality of interconnect structures,
wherein each interconnect structure of the plurality of interconnect structures contacts the second electrode layer portion of the underlying memory device.

11. The method of claim 10, wherein a thickness of the capping spacer layer is smaller than thicknesses of other spacer layers of the plurality of spacer layers.

12. The method of claim 10, wherein parts of the capping spacer layer are disposed on sides of the plurality of memory devices between two other spacer layers of the plurality of spacer layers.

13. The method of claim 10, wherein depositing the plurality of spacer layers comprises:
depositing a first spacer layer on side surfaces and a top surface of the second electrode layer of each memory device;
removing portions of the first spacer layer from the top surface of the second electrode layer of each memory device;
depositing a stacked spacer layer arrangement on remaining portions of the first spacer layer and on the top surface of the second electrode layer of each memory device,
wherein the stacked spacer layer arrangement comprises:
the capping spacer layer; and
one or more additional spacer layers on the capping spacer layer; and
removing portions of the one or more additional spacer layers from the top surface of the second electrode layer of each memory device to expose underlying portions of the capping spacer layer.

14. The method of claim 10, wherein depositing the plurality of spacer layers comprises:
depositing a stacked spacer layer arrangement on side surfaces and a top surface of the second electrode layer of each memory device;
wherein the stacked spacer layer arrangement comprises:
a first spacer layer); and
one or more additional spacer layers on the first spacer layer;
removing portions of the stacked spacer layer arrangement from the top surface of the second electrode layer of each memory device; and
depositing the capping spacer layer on remaining portions of the stacked spacer layer arrangement and on the top surface of the second electrode layer of each memory device.

15. A semiconductor device, comprising:
a device layer;
an interconnect layer disposed over the device layer,
wherein the interconnect layer comprises a plurality of dielectric layers,
wherein the plurality of dielectric layers comprise a plurality of metal lines disposed in the plurality of dielectric layers,
wherein a first metal line in a first dielectric layer of the plurality of dielectric layers is spaced apart from a second metal line in a second dielectric layer the plurality of dielectric layers, and
wherein the first metal line is electrically coupled to the second metal line by a first via in the second dielectric layer;
a plurality of memory devices arranged side-by-side in the interconnect layer,
wherein each memory device of the plurality of memory devices comprises:
a first electrode layer;
a memory device structure on the first electrode layer; and
a second electrode layer on the memory device structure,
wherein the interconnect layer further comprises a plurality of second vias and a plurality of third metal lines disposed in the second dielectric layer,
wherein a second via of the plurality of second vias is disposed between a third metal line of the plurality of third metal lines and the second electrode layer of a memory device of the plurality of memory devices,
wherein the second via contacts a surface of the second electrode layer,
wherein a bottom portion of the second via is disposed through portions of a spacer layer, and
wherein the portions of the spacer layer are disposed on the second electrode layer.

16. The semiconductor device of claim 15, wherein the first via is in a same via level as the plurality of second vias, and
wherein the plurality of third metal lines are in a same metallization level as the second metal line.

17. The semiconductor device of claim 15, wherein the second via is further disposed in the first dielectric layer, and
wherein a vertical dimension of the second via is larger than a vertical dimension of the first via.

18. The semiconductor device of claim 15, wherein additional portions of the spacer layer extend around sides of the plurality of memory devices, and
wherein an additional spacer layer is disposed between the additional portions of the spacer layer and a memory device of the plurality of memory devices.

19. The semiconductor device of claim 15, wherein additional portions of the spacer layer extend around sides of the plurality of memory devices, and
wherein a plurality of additional spacer layers are disposed on the additional portions of the spacer layer.

20. The semiconductor device of claim 15, further comprising a plurality of additional spacer layers disposed on sides of the plurality of memory devices,
wherein additional portions of the spacer layer are disposed on top of the plurality of additional spacer layers.
